(19) United States
(12) Patent Application Publication
(10) Pub. No.: US 2025/0141428 A1
(43) Pub. Date: May 1, 2025

(54) RESONATOR WITH COMPLEMENTARILY ORIENTED PIEZOELECTRIC STRUCTURE

(71) Applicant: Murata Manufacturing Co., Ltd., Nagaokakyo-shi (JP)

(72) Inventors: Drew MOROSIN, Oxnard, CA (US); John P. Koulakis, Los Angeles, CA (US); Garrett Williams, San Mateo, CA (US); Soumya Yandrapalli, Amsterdam (NL); Sean Mchugh, San Mateo, CA (US)

(21) Appl. No.: 18/924,391

(22) Filed: Oct. 23, 2024

Related U.S. Application Data
(60) Provisional application No. 63/593,451, filed on Oct. 26, 2023.

(51) Int. Cl. H03H 9/17; H03H 9/02; H03H 9/13

(52) U.S. Cl. CPC H03H 9/178; H03H 9/02031; H03H 9/02228; H03H 9/13; H03H 9/173

(57) ABSTRACT

An acoustic resonator is provided that includes a first piezoelectric layer of a material with a first crystallographic orientation and a second piezoelectric layer coupled to the first piezoelectric layer and comprising a material with a second crystallographic orientation, such that a piezoelectric tensor of the second piezoelectric layer is an opposite polarity to a piezoelectric tensor of the fist piezoelectric layer. Moreover, an interdigital transducer (IDT) including interleaved fingers is disposed on a surface of the first piezoelectric layer; and a first dielectric coating layer is disposed over the IDT and the first piezoelectric layer.

### CROSS REFERENCE TO RELATED APPLICATIONS

This application claims priority to U.S. Patent Provisional Application No. 63/593,451, filed Oct. 26, 2023, the entire contents of which are hereby incorporated by reference.

### TECHNICAL FIELD

This disclosure relates to radio frequency filters using acoustic wave resonators, and, more specifically, to a filter including an acoustic wave resonator with a complementarily oriented piezoelectric structure.

### BACKGROUND

A radio frequency (RF) filter is a two-port device configured to pass some frequencies and to stop other frequencies, where “pass” means transmit with relatively low signal loss and “stop” means block or substantially attenuate. The range of frequencies passed by a filter is referred to as the “passband” of the filter. The range of frequencies stopped by such a filter is referred to as the “stopband” of the filter. A typical RF filter has at least one passband and at least one stop-band. Specific requirements on a passband or stop-band may depend on the specific application. For example, in some cases a “passband” may be defined as a frequency range where the insertion loss of a filter is better than a defined value such as 1 dB, 2 dB, or 3 dB, while a “stop-band” may be defined as a frequency range where the rejection of a filter is greater than a defined value such as 20 dB, 30 dB, 40 dB, or greater depending on application.

RF filters are used in communications systems where information is transmitted over wireless links. For example, RF filters may be found in the RF front ends of cellular base stations, mobile telephone and computing devices, satellite transceivers and ground stations, IoT (Internet of Things) devices, laptop computers and tablets, fixed point radio links, and other communications systems. RF filters are also used in radar and electronic and information warfare systems.

Performance enhancements to the RF filters in a wireless system can have a broad impact to system performance. Improvements in RF filters can be leveraged to provide system performance improvements, such as larger cell size, longer battery life, higher data rates, greater network capacity, lower cost, enhanced security, higher reliability, etc. These improvements can be realized at many levels of the wireless system both separately and in combination, for example, at the RF module, RF transceiver, mobile or fixed sub-system, or network levels. As the demand for RF filters operating at higher frequencies continues to increase, there is a need for improved filters that can operate at different frequency bands while also improving the manufacturing processes for making such filters.

The transversely-excited film bulk acoustic resonator (XBAR) is an acoustic resonator structure for use in microwave filters. An XBAR resonator typically comprises an interdigital transducer (IDT) formed on a thin floating layer, or diaphragm, of a single-crystal piezoelectric material. The IDT includes a first set of parallel fingers, extending from a first busbar and a second set of parallel fingers extending from a second busbar. The first and second sets of parallel fingers are interleaved. A microwave signal applied to the IDT excites a shear primary acoustic wave in the piezoelectric diaphragm. XBAR resonators provide very high electromechanical coupling and high frequency capability. XBAR resonators may be used in a variety of RF filters including band-reject filters, bandpass filters, duplexers, and multiplexers. XBARs are well suited for use in filters for communications bands with frequencies above 3 GHz.

### SUMMARY

Accordingly, as described herein, an acoustic resonator and filter device incorporating the same is provided having a complementarily oriented piezoelectric structure with a dielectric coating layer having a thickness to provide improved coupling for higher order modes of the filter device.

Thus, according to an exemplary aspect, an acoustic resonator is provided that includes a first piezoelectric layer comprising a material with a first crystallographic orientation; a second piezoelectric layer attached to the first piezoelectric layer and comprising a material with a second crystallographic orientation, such that a piezoelectric tensor of the second piezoelectric layer is an opposite polarity to a piezoelectric tensor of the first piezoelectric layer; an interdigital transducer (IDT) including a plurality of interleaved fingers disposed on a surface of the first piezoelectric layer; and a first dielectric coating layer disposed over the IDT and the first piezoelectric layer, the first dielectric coating layer having a thickness that is less than 0.5 times a combined thickness of the first and second piezoelectric layers.

In another aspect, the acoustic resonator includes a second dielectric coating layer disposed over a surface of the second piezoelectric layer that is opposite the first piezoelectric layer.

In another aspect of the acoustic resonator, the first and second piezoelectric layers and the IDT are configured such that radio frequency signals applied to the IDT primarily excites a shear acoustic mode in the first and second piezoelectric layers. In this aspect, the shear acoustic mode comprises a bulk shear wave having a propagation direction perpendicular to a direction of a primarily laterally excited electric field generated by the IDT, and the electric field being primarily laterally excited when atomic motion of the bulk shear wave is primarily horizontal in the first and second piezoelectric layers, while the bulk shear wave propagates in a direction primarily perpendicular to the direction of atomic motion.

In another aspect of the acoustic resonator, the first and second dielectric coating layers each have a thickness based on a largest net stress of the respective materials of the first and second piezoelectric layers when the primarily shear acoustic mode is excited in the first and second piezoelectric layers.

In another aspect, the acoustic resonator includes a substrate that includes a base and an intermediate layer, wherein each of the first and second piezoelectric layers including a portion that is over a cavity that extends at least partially in the intermediate layer of the substrate. Moreover, the surface of the first piezoelectric layer on which the IDT is disposed can face the cavity.

In another aspect, the IDT of the acoustic resonator includes a first busbar and a second busbar that each extend in a first direction from a first end to a second end thereof, a first plurality of electrode fingers extending from the first busbar in a second direction towards the second busbar, with the second direction intersecting the first direction, and a second plurality of electrode fingers extending from the second busbar in the second direction towards to the first busbar, such that the first and second plurality of electrode fingers form the plurality of interleaved fingers of the IDT.

In another aspect, the acoustic resonator includes a third piezoelectric layer disposed on a surface of the second piezoelectric layer opposite the first piezoelectric layer, the third piezoelectric layer comprising a same material as the first piezoelectric layer having the first crystallographic orientation.

In another aspect of the acoustic resonator, the material of first piezoelectric layer comprises first Euler angles and the material of second piezoelectric layer comprises second Euler angles rotated by approximately 180° about at least one axis relative to the first Euler angles.

In another aspect of the acoustic resonator, the acoustic resonator is configured to operate in a third order antisymmetric (A3) mode and the first dielectric coating layer has a thickness configured to increase a coupling coefficient of the acoustic resonator in the A3 mode.

Moreover, according to an exemplary aspect, an acoustic resonator is provided that is configured for operating in at least one of a third order antisymmetric (A3) mode and fourth order symmetric (S4) mode. In this aspect, the acoustic resonator includes a first piezoelectric layer comprising a material with a first crystallographic orientation; a second piezoelectric layer coupled to the first piezoelectric layer and comprising a material with a second crystallographic orientation, such that a piezoelectric tensor of the second piezoelectric layer is an opposite polarity to a piezoelectric tensor of the first piezoelectric layer; an interdigital transducer (IDT) including a plurality of interleaved fingers disposed on a surface of the first piezoelectric layer; and a first dielectric coating layer disposed over the IDT and the first piezoelectric layer.

In another exemplary aspect of the acoustic resonator, the first dielectric coating layer has a thickness that is less than 0.5 times a combined thickness of the first and second piezoelectric layers.

In another exemplary aspect of the acoustic resonator, the first dielectric coating layer has a thickness x that is between 0.15 and 1.0 times a combined thickness of the first and second piezoelectric layers and the acoustic resonator is configured to operate in the third order antisymmetric (A3) mode.

In another exemplary aspect, the acoustic resonator according includes a second dielectric coating layer disposed over a surface of the second piezoelectric layer that is opposite the first piezoelectric layer, the second dielectric layer have a thickness y. In this aspect, 0≤y≤−0.35x²+1.23x−0.18, wherein x is a ratio of the thickness of the first dielectric coating layer to the combined thickness of the first and second piezoelectric layers, and wherein y is a ratio of a thickness of the second dielectric coating layer to the combined thickness of the first and second piezoelectric layers.

In another exemplary aspect, the acoustic resonator according includes a second dielectric coating layer disposed over a surface of the second piezoelectric layer that is opposite the first piezoelectric layer, the second dielectric layer have a thickness that is between 0.15 and 1.0 times a combined thickness of the first and second piezoelectric dielectric layers. In this aspect, 0≤x≤−0.35y²+1.23y−0.18, wherein x is a ratio of a thickness of the first dielectric coating layer to the combined thickness of the first and second piezoelectric layers, and wherein y is a ratio of the thickness of the second dielectric coating layer to the combined thickness of the first and second piezoelectric layers.

In another exemplary aspect of the acoustic resonator, the first and second piezoelectric layers and the IDT are configured such that radio frequency signals applied to the IDT excites a primary shear acoustic mode in the first and second piezoelectric layers. In this aspect, the shear acoustic mode comprises a bulk shear wave having a propagation direction perpendicular to a direction of a primarily laterally excited electric field generated by the IDT, and the electric field being primarily laterally excited when atomic motion of the bulk shear wave is primarily horizontal in the first and second piezoelectric layers, while the bulk shear wave propagates in a direction primarily perpendicular to the direction of atomic motion.

In another exemplary aspect of the acoustic resonator, the first and second dielectric coating layers each have a thickness based on a largest net stress of the respective materials of the first and second piezoelectric layers when the primary shear acoustic mode is excited in the first and second piezoelectric layers.

In another exemplary aspect, the acoustic resonator further includes a substrate that includes a base and an intermediate layer, wherein each of the first and second piezoelectric layers including a portion that is over a cavity that extends at least partially in the intermediate layer of the substrate, and the surface of the first piezoelectric layer on which the IDT is disposed faces the cavity.

In another exemplary aspect, the acoustic resonator further includes a third piezoelectric layer disposed on a surface of the second piezoelectric layer opposite the first piezoelectric layer, the third piezoelectric layer comprising a same material as the first piezoelectric layer having the first crystallographic orientation. Moreover, the material of first piezoelectric layer comprises first Euler angles and the material of second piezoelectric layer comprises second Euler angles rotated by approximately 180° about at least one axis relative to the first Euler angle.

In yet another exemplary aspect, a radio frequency module is provided that includes a filter device having a plurality of acoustic resonators configured to operate in at least one of a third order antisymmetric (A3) mode and fourth order symmetric (S4) mode; and a radio frequency circuit coupled to the filter device, the filter device and the radio frequency circuit being enclosed within a common package. In this aspect, at least one of the plurality of acoustic resonators includes a first piezoelectric layer comprising a material with a first crystallographic orientation; a second piezoelectric layer coupled to the first piezoelectric layer and comprising a material with a second crystallographic orientation, such that a piezoelectric tensor of the second piezoelectric layer is an opposite polarity to a piezoelectric tensor of the first piezoelectric layer; an interdigital transducer (IDT) including a plurality of interleaved fingers disposed on a surface of the first piezoelectric layer; a first dielectric coating layer disposed over the IDT and the first piezoelectric layer; and a second dielectric coating layer disposed over a surface of the second piezoelectric layer that is opposite the first piezoelectric layer. Moreover, one of the first and second dielectric layers has a thickness that is between 0.15 and 1.0 times a combined thickness of the first and second piezoelectric layers, and another of the first and second dielectric layers has thickness, such that 0≤y≤−0.35x²+1.23x−0.18. In this aspect, x is a ratio of the thickness of the first dielectric coating layer to the combined thickness of the first and second piezoelectric layers, and y is a ratio of a thickness of the second dielectric coating layer to the combined thickness of the first and second piezoelectric layers.

The above simplified summary of example aspects serves to provide a basic understanding of the present disclosure. This summary is not an extensive overview of all contemplated aspects and is intended to neither identify key or critical elements of all aspects nor delineate the scope of any or all aspects of the present disclosure. Its sole purpose is to present one or more aspects in a simplified form as a prelude to the more detailed description of the disclosure that follows. To the accomplishment of the foregoing, the one or more aspects of the present disclosure include the features described and exemplary pointed out in the claims.

### BRIEF DESCRIPTION OF THE DRAWINGS

The accompanying drawings, which are incorporated into and form a part of this specification, illustrate one or more example aspects of the present disclosure and, together with the detailed description, serve to explain their principles and implementations.

FIG. 1A includes a schematic plan view and a schematic cross-sectional view of a transversely-excited film bulk acoustic resonator (XBAR).

FIG. 1B shows a schematic cross-sectional view of an alternative configuration of an XBAR.

FIG. 2A is an expanded schematic cross-sectional view of a portion of the XBAR of FIG. 1A.

FIG. 2B is an expanded schematic cross-sectional view of an alternative configuration of the XBAR of FIG. 1A.

FIG. 2C is an expanded schematic cross-sectional view of another alternative configuration of the XBAR of FIG. 1A.

FIG. 2D is an expanded schematic cross-sectional view of another alternative configuration of the XBAR of FIG. 1A.

FIG. 2E is an expanded schematic cross-sectional view of a portion of a solidly-mounted XBAR (SM XBAR).

FIG. 3A is a schematic cross-sectional view of an XBAR according to an exemplary aspect.

FIG. 3B is an alternative schematic cross-sectional view of an XBAR according to an exemplary aspect.

FIG. 4 is a graphic illustrating a shear horizontal acoustic mode in an XBAR.

FIG. 5A is a schematic block diagram of a filter using XBARs of FIGS. 1A and/or 1B.

FIG. 5B is a schematic diagram of a radio frequency module that includes an acoustic wave filter device according to an exemplary aspect.

FIG. 6A is a schematic cross-sectional view of an acoustic wave resonator with a complementarily oriented piezoelectric structure according to an exemplary aspect.

FIG. 6B is a schematic cross-sectional view of an acoustic wave resonator with a complementarily oriented piezoelectric structure according to another exemplary aspect.

FIG. 6C is a schematic cross-sectional view of an acoustic wave resonator with a complementarily oriented piezoelectric structure according to another exemplary aspect.

FIG. 6D is a schematic cross-sectional view of an acoustic wave resonator with a complementarily oriented piezoelectric structure according to another exemplary aspect.

FIG. 7A illustrates a plurality of graphs for varying thickness of top and bottom dielectric coating layers for higher order symmetric and anti-symmetric modes of an acoustic resonator such as that having the configuration in FIG. 2A.

FIG. 7B illustrates a plurality of graphs for varying thickness of top and bottom dielectric coating layers for higher order symmetric and anti-symmetric modes of an acoustic resonator with the COP structure, such as that having the configuration in FIG. 6A.

FIG. 7C illustrates an alternative representation of plurality of graphs shown in FIG. 7B for varying thickness of top and bottom dielectric coating layers for higher order symmetric and anti-symmetric modes of an acoustic resonator with the COP structure according to an exemplary aspect.

FIG. 7D illustrates an alternative representation of a graph shown in FIG. 7B for varying thickness of top and bottom dielectric coating layers for a high coupling coefficient k² for operating in the A₃ mode.

FIG. 7E illustrates a graph fitting a curve to the region shown in FIG. 7D for coating ratio of the COP structure provided for the high coupling coefficient k² for operating in the A₃ mode.

FIG. 7F illustrates a plurality of graphs for varying thicknesses of top and bottom dielectric coating layers for higher order symmetric and anti-symmetric modes of an acoustic resonator with the three layer COP structure of FIG. 6B.

FIG. 7G illustrates a plurality of graphs for varying thicknesses of top and sandwich dielectric coating layers for higher order symmetric and anti-symmetric modes of an acoustic resonator with the COP sandwich structure (i.e., having a dielectric layer between two piezoelectric layers), such as that having the configuration in FIG. 6C.

FIG. 7H illustrates a plurality of graphs for varying thicknesses of top and sandwich dielectric coating layers for higher order symmetric and anti-symmetric modes of an acoustic resonator with the COP sandwich structure (i.e., having a dielectric layer between two piezoelectric layers), but without a bottom dielectric coating layer, such as that having the configuration in FIG. 6D according to an exemplary aspect.

FIG. 71 illustrates an alternative representation of a graph shown in FIG. 7B for varying thickness of top and bottom dielectric coating layers for a high coupling coefficient k2 for operating in the S2 mode according to an exemplary aspect.

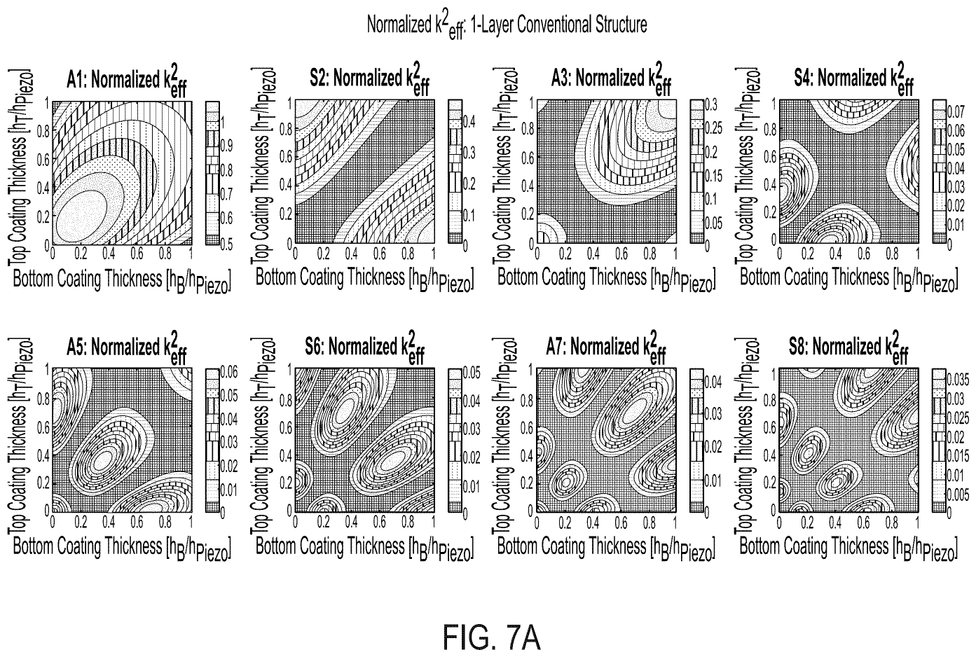

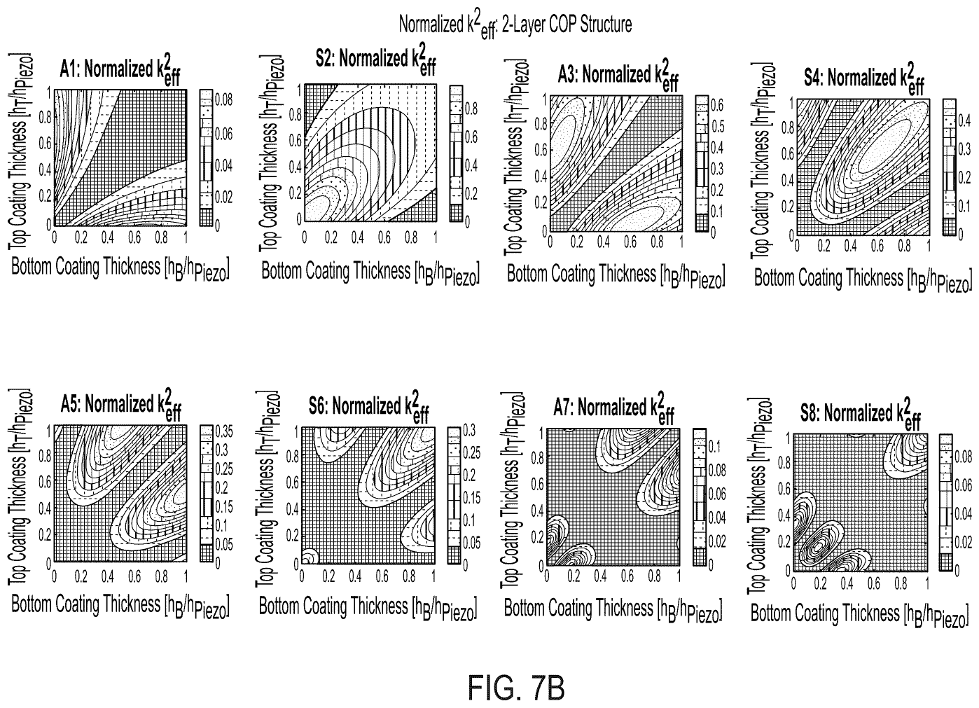

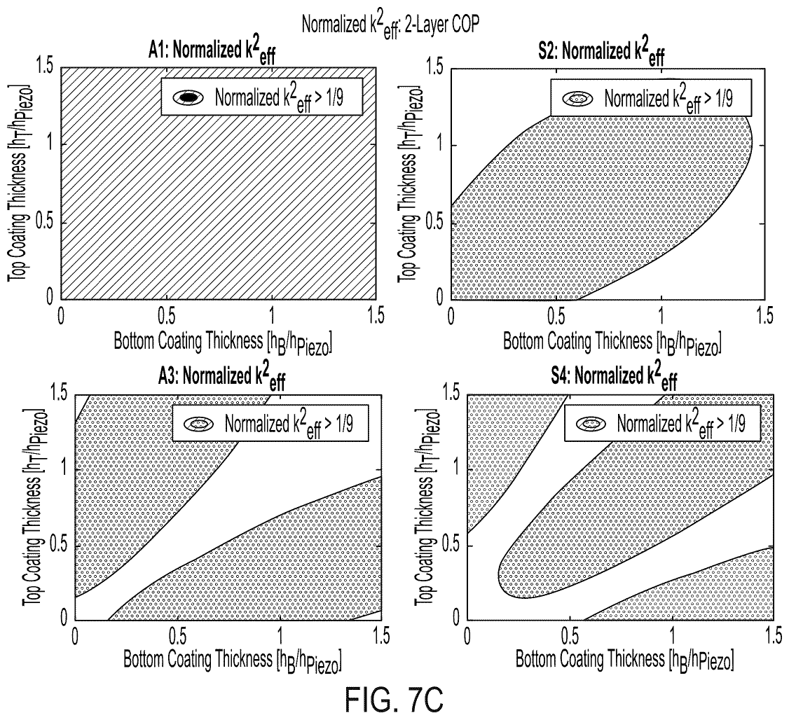

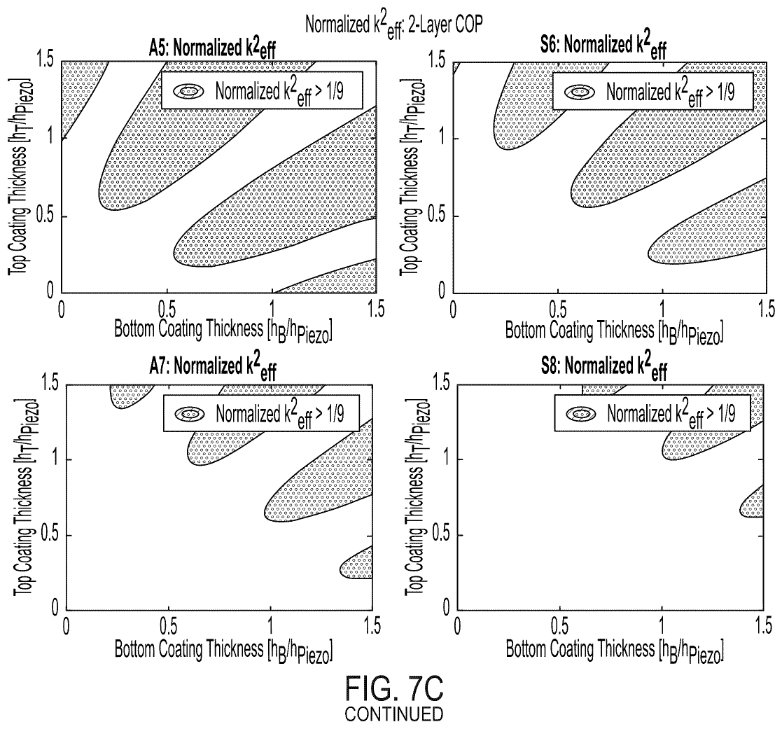

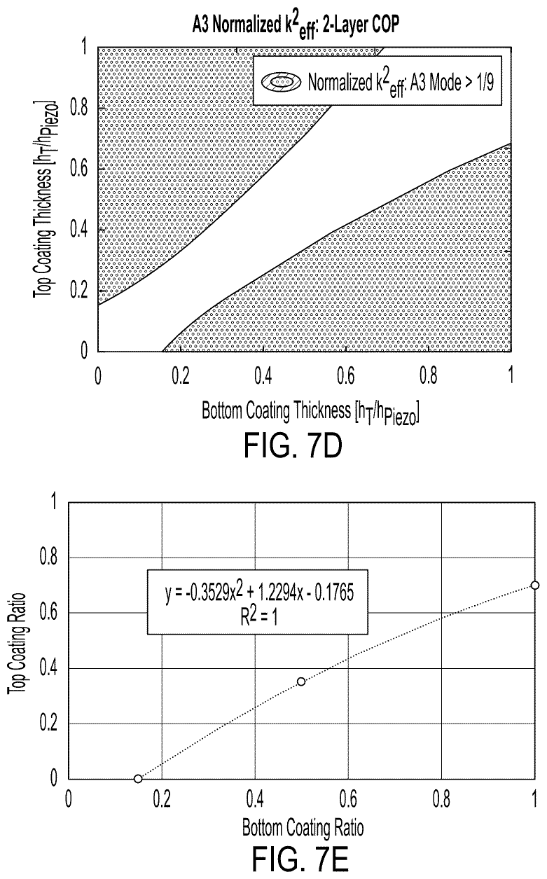

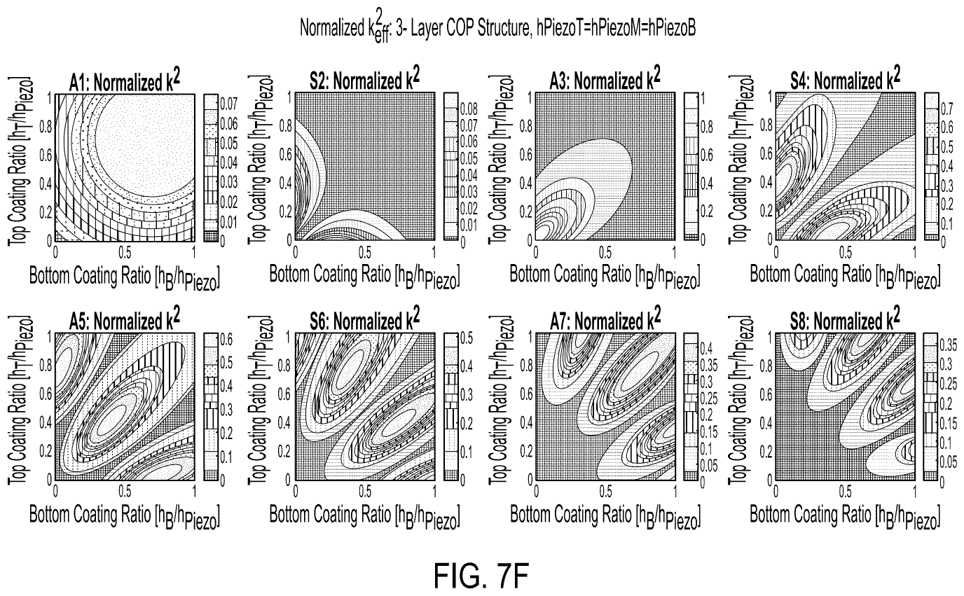

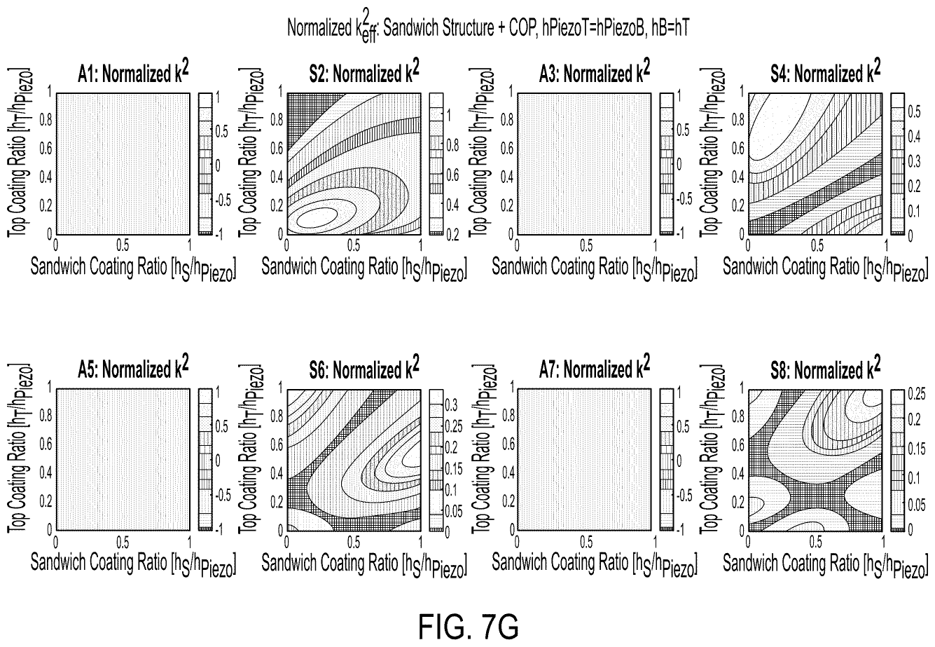

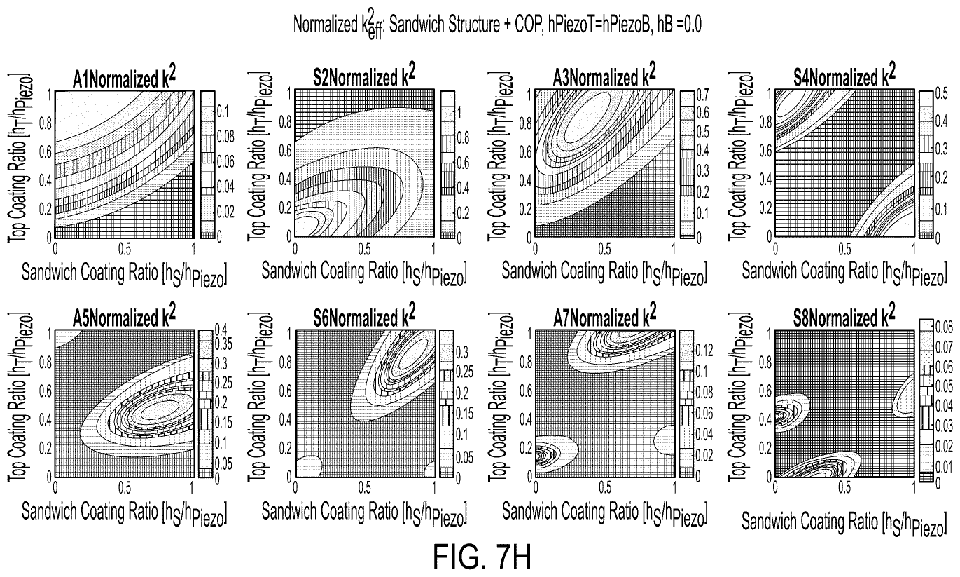

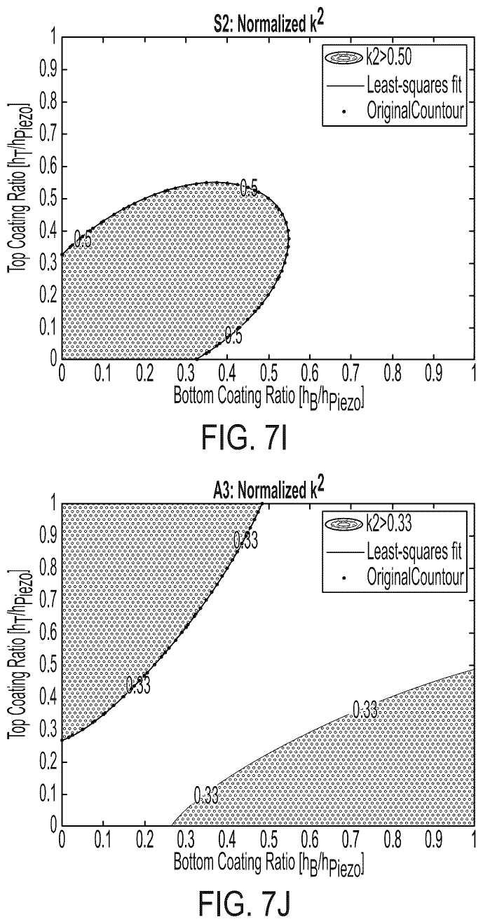

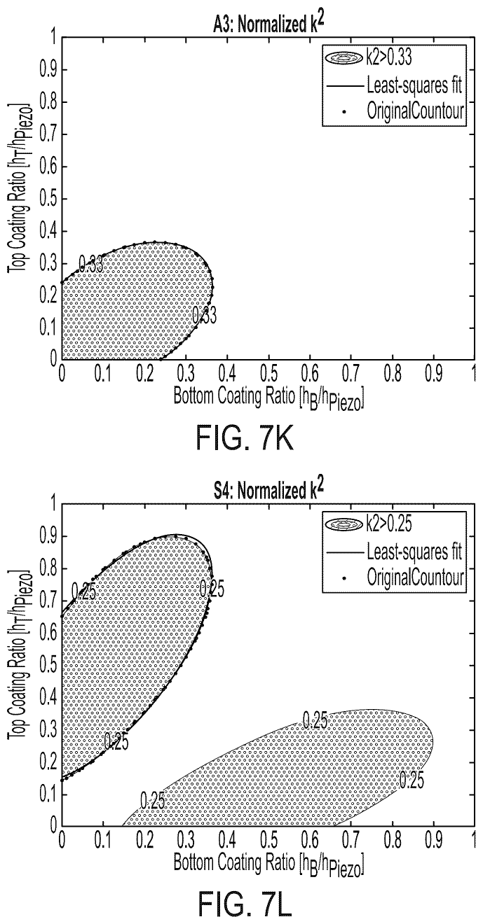

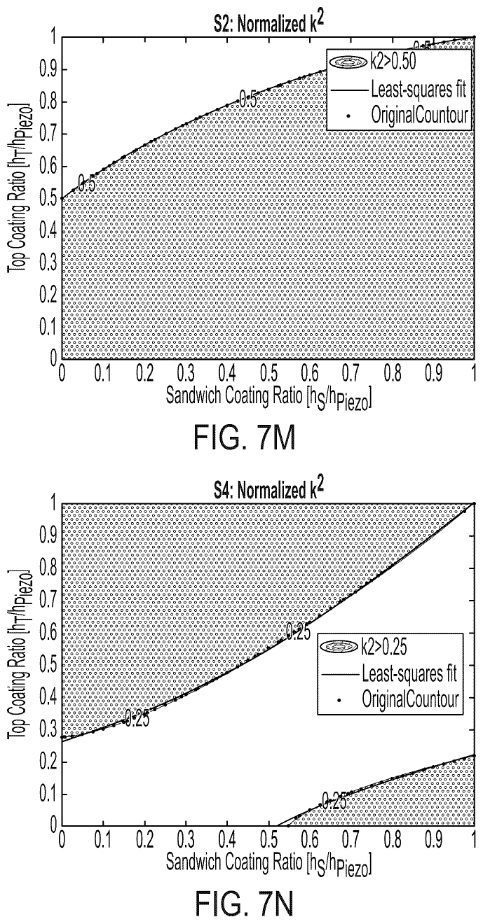

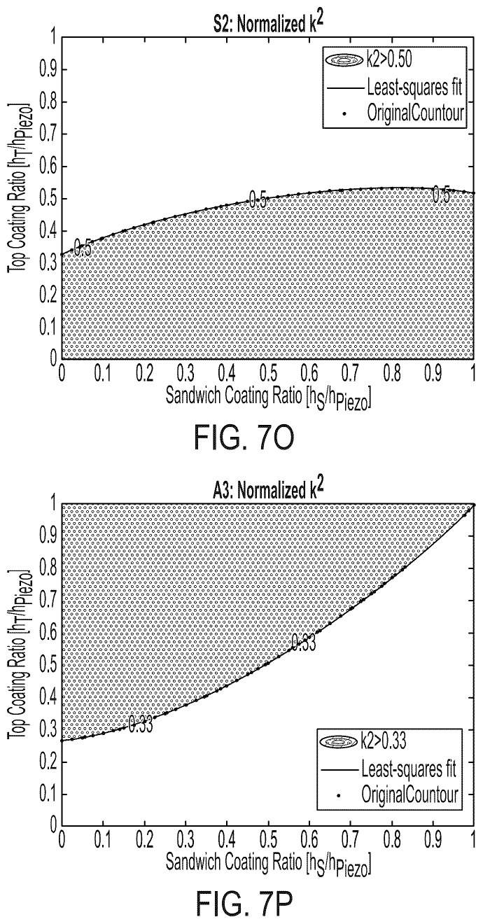

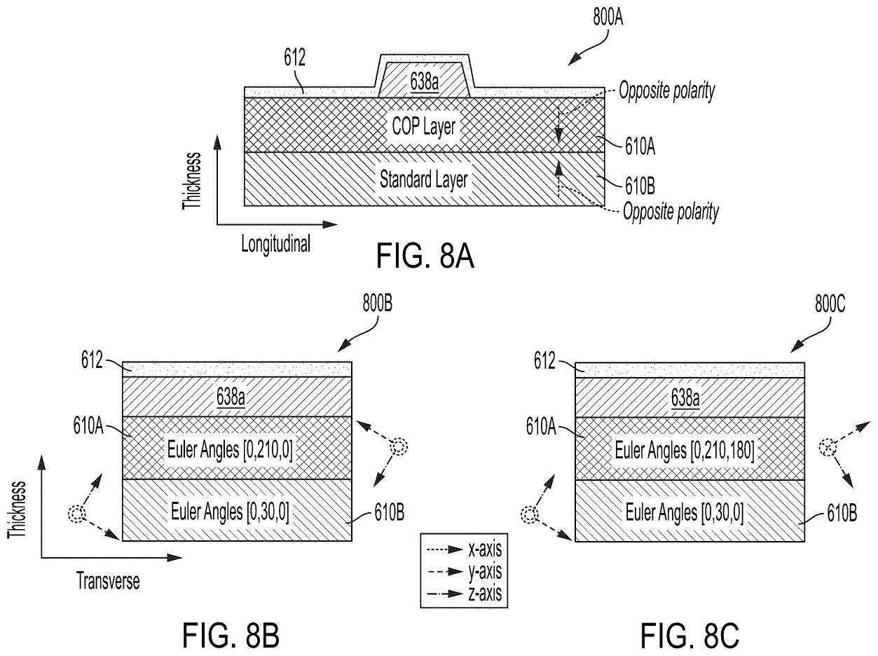

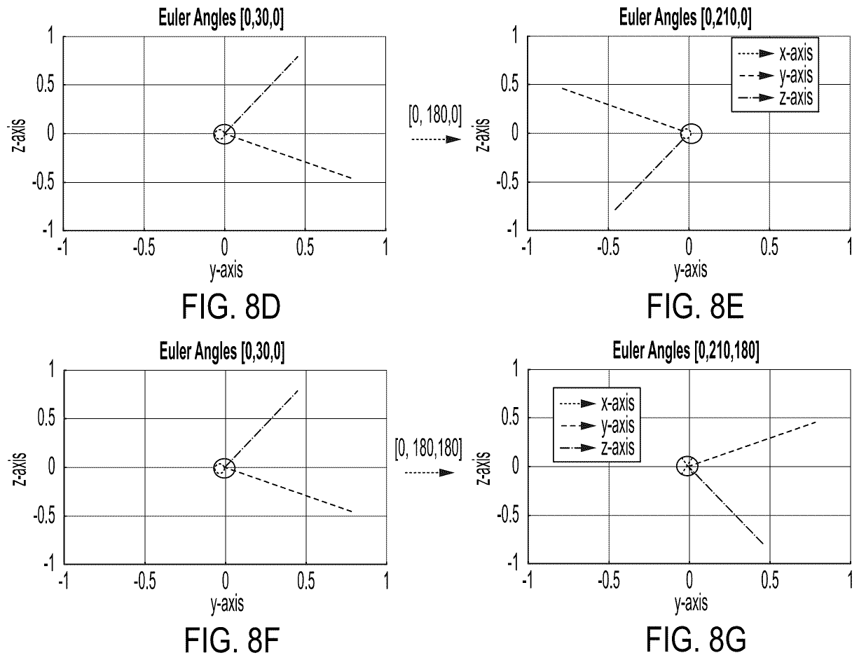

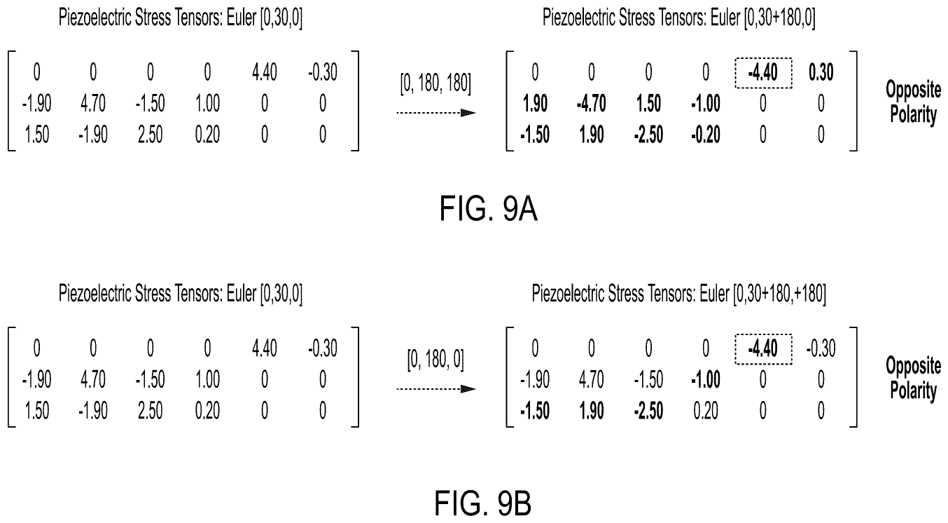

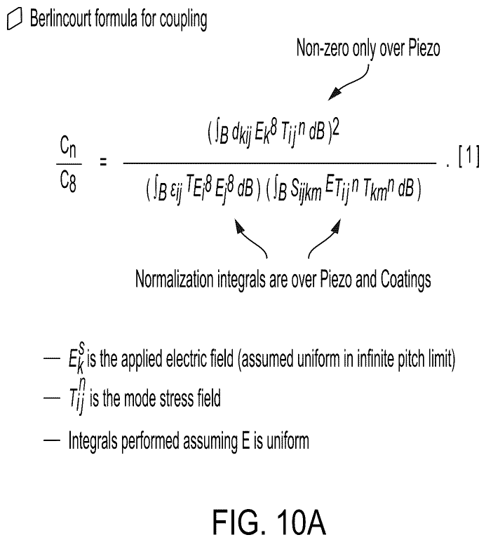

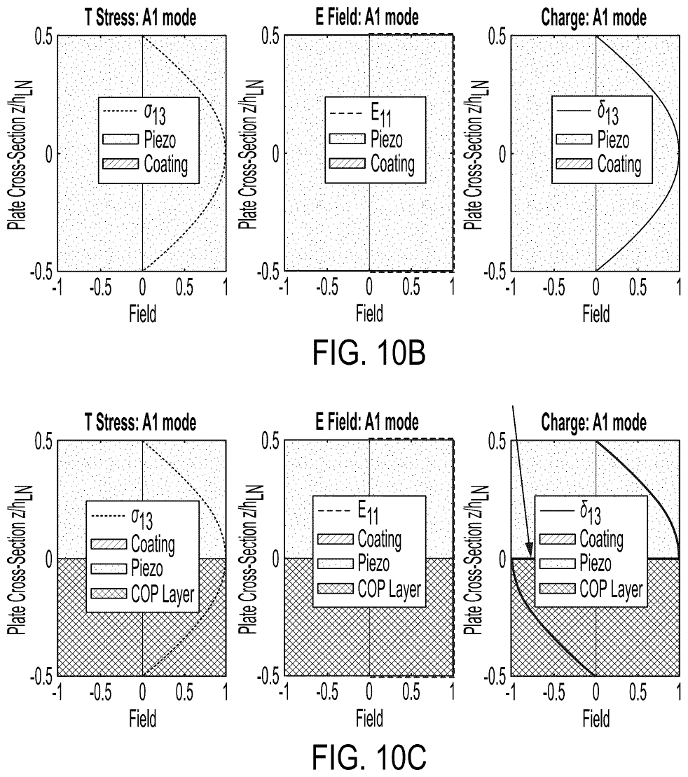

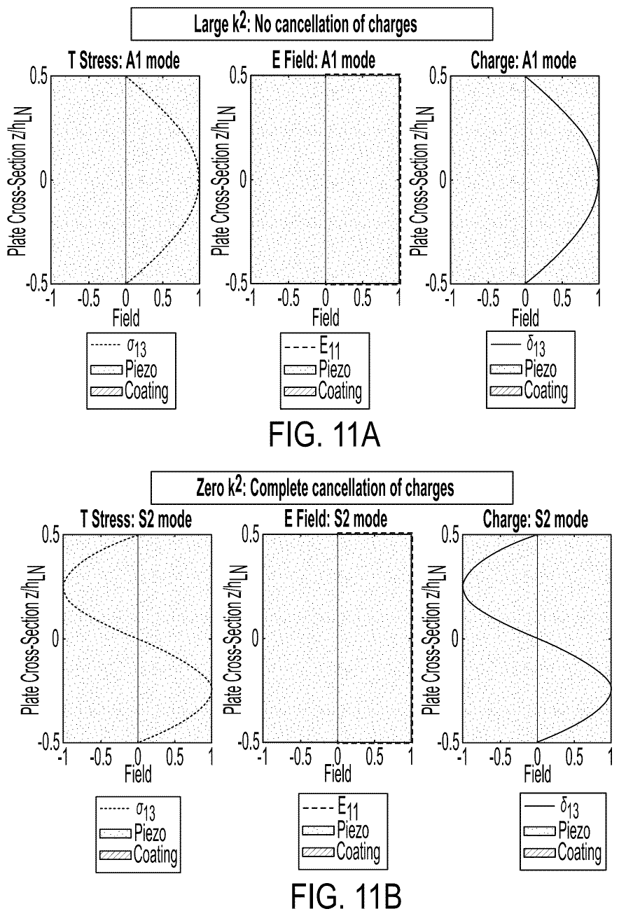

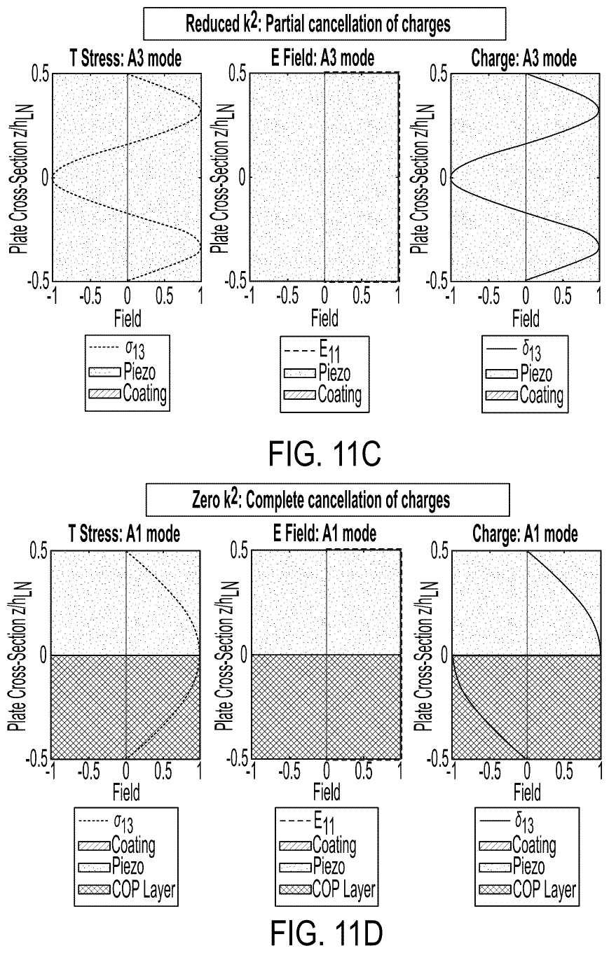

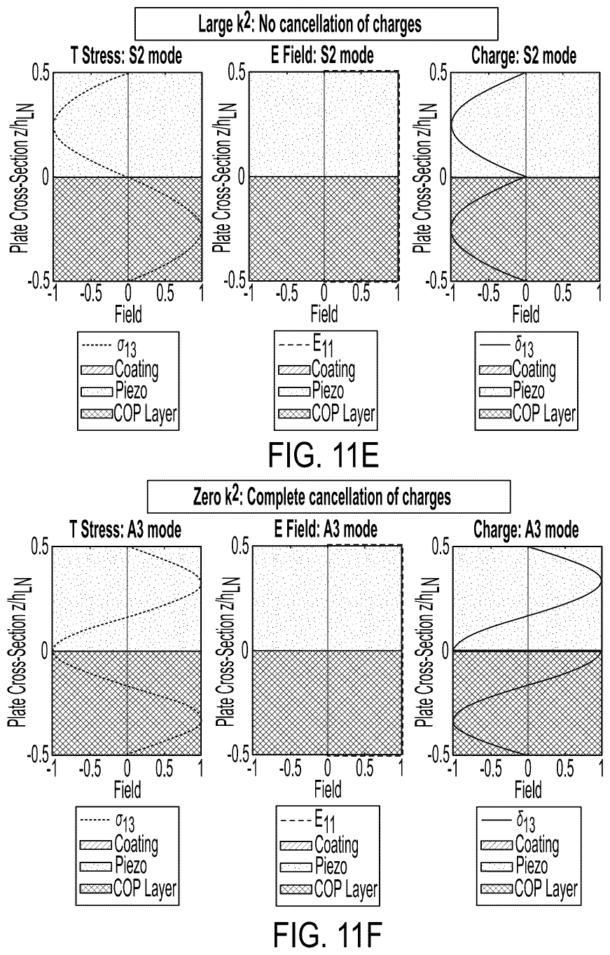

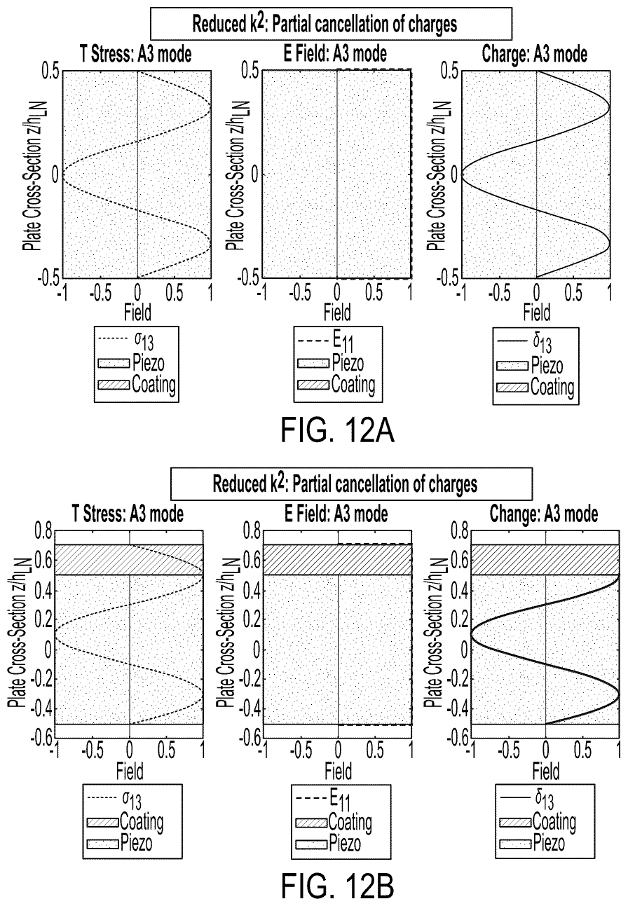

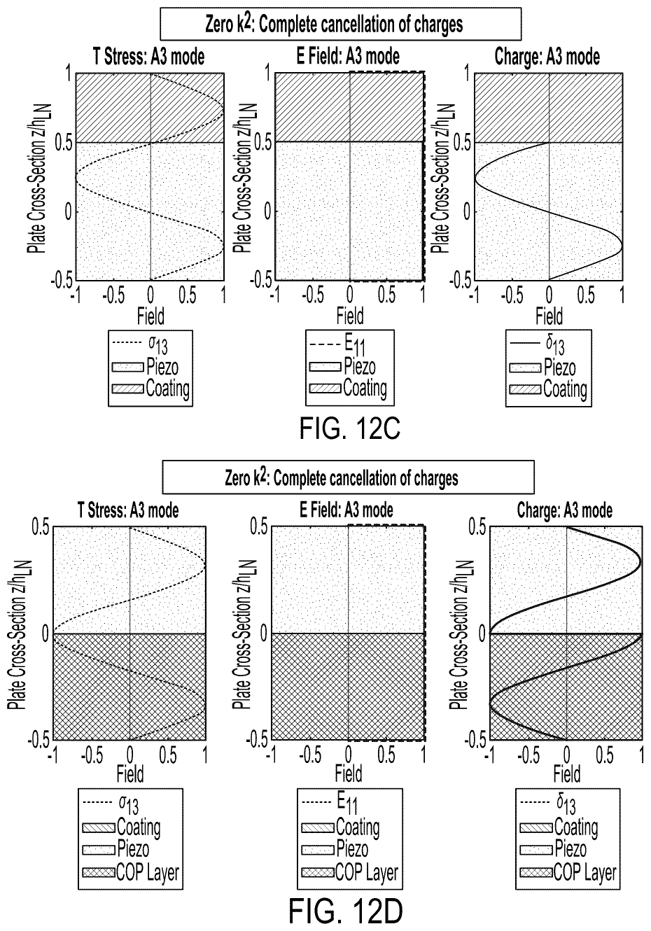

FIG. 7J illustrates an alternative representation of a graph shown in FIG. 7B for varying thickness of top and bottom dielectric coating layers for a high coupling coefficient k2 for operating in the A3 mode according to an exemplary aspect.

FIG. 7K illustrates an alternative representation of a graph shown in FIG. 7F for varying thickness of top and bottom dielectric coating layers for a high coupling coefficient k2 for operating in the A3 mode according to an exemplary aspect.

FIG. 7L illustrates an alternative representation of a graph shown in FIG. 7F for varying thickness of top and bottom dielectric coating layers for a high coupling coefficient k2 for operating in the S4 mode according to an exemplary aspect.

FIG. 7M illustrates an alternative representation of a graph shown in FIG. 7G for varying thickness of top and sandwich dielectric coating layers for a high coupling coefficient k2 for operating in the S2 mode according to an exemplary aspect.

FIG. 7N illustrates an alternative representation of a graph shown in FIG. 7G for varying thickness of top and sandwich dielectric coating layers for a high coupling coefficient k2 for operating in the S4 mode according to an exemplary aspect.

FIG. 70 illustrates an alternative representation of a graph shown in FIG. 7H for varying thickness of top and sandwich dielectric coating layers for a high coupling coefficient k2 for operating in the S2 mode according to an exemplary aspect.

FIG. 7P illustrates an alternative representation of a graph shown in FIG. 7H for varying thickness of top and sandwich dielectric coating layers for a high coupling coefficient k2 for operating in the A3 mode according to an exemplary aspect.

FIG. 8A illustrates a cross-sectional view of an acoustic wave resonator with a complementarily oriented piezoelectric structure according to an exemplary aspect.

FIGS. 8B and 8C are cross-sectional views of an acoustic wave resonator with a complementarily oriented piezoelectric structure according to exemplary aspects in which Euler angles for each material of each piezoelectric layer are shown.

FIGS. 8D to 8G illustrate graphs demonstrating the rotation of approximately 180 degrees to provide for the different Euler angles of the COP structure.

FIGS. 9A and 9B illustrate charts of piezoelectric stress tensors of an acoustic wave resonator with a complementarily oriented piezoelectric structure according to an exemplary aspect.

FIG. 10A illustrate a formula for determining coupling according to the COP structure described herein.

FIGS. 10B and 10C illustrate charts for the stress profile, uniform E-field throughout the structure and charge profile for a given mode, comparing a standard XBAR structure to an XBAR having a COP structure as described herein.

FIGS. 11A-11C illustrate charts for the stress profile, uniform E-field throughout the structure and charge profile for a standard XBAR structure as described herein.

FIGS. 11D-11F illustrate charts for the stress profile, uniform E-field throughout the structure and charge profile for an XBAR structure with a COP structure according to an exemplary aspect.

FIGS. 12A-12C illustrate charts for the stress profile, uniform E-field throughout the structure and charge profile for a standard XBAR structure as described herein and including a dielectric layer.

FIGS. 12D-12F illustrate charts for the stress profile, uniform E-field throughout the structure and charge profile for an XBAR structure with a COP structure that also has a dielectric coating layer according to an exemplary.

Throughout this description, elements appearing in figures are assigned three-digit or four-digit reference designators, where the two least significant digits are specific to the element and the one or two most significant digits are the figure number where the element is first introduced. An element that is not described in conjunction with a figure may be presumed to have the same characteristics and function as a previously described element having the same reference designator.

### DETAILED DESCRIPTION

Various aspects of the disclosed acoustic resonator, filter device and method of manufacturing the same are now described with reference to the drawings, wherein like reference numerals are used to refer to like elements throughout. In the following description, for purposes of explanation, numerous specific details are set forth in order to promote a thorough understanding of one or more aspects of the disclosure. It may be evident in some or all instances, however, that any aspects described below can be practiced without adopting the specific design details described below. In other instances, well-known structures and devices are shown in block diagram form in order to facilitate description of one or more aspects. The following presents a simplified summary of one or more aspects of the invention in order to provide a basic understanding thereof.

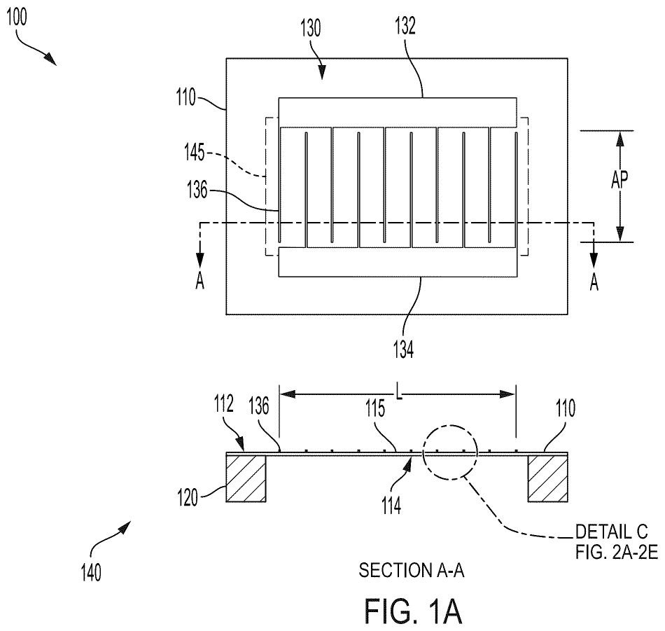

FIG. 1A shows a simplified schematic top view and an orthogonal cross-sectional view of a bulk acoustic resonator device, namely a transversely excited film bulk acoustic resonator (XBAR) 100. XBAR resonators, such as the resonator 100, may be used in a variety of RF filters including band-rejection filters, bandpass filters, duplexers, and multiplexers. XBARs are particularly suited for use in filters for communications bands with frequencies above 3 GHz.

In general, the XBAR 100 includes a conductor pattern (e.g., a thin film metal layer) formed at one or both surfaces of a piezoelectric layer 110 (herein piezoelectric plate or piezoelectric layer may be used interchangeably) having parallel front side 112 and a back side 114, respectively (also referred to generally first and second surfaces, respectively). It should be appreciated that the term “parallel” generally refers to the front side 112 and back side 114 being opposing to each other and that the surfaces are not necessarily planar and exactly parallel to each other. For example, due to the manufacturing variances result from the deposition process, the front side 112 and back side 114 may have undulations of the surface as would be appreciated to one skilled in the art. Moreover, the term “substantially” as used herein is used to describe when components, parameters and the like are generally the same (i.e., “substantially constant”), but may vary slightly (e.g., within an acceptable threshold or percentage) in practice due to possible manufacturing variances as would be appreciated to one skilled in the art. For purposes of this disclosure, the use of the term “or” in the claims is used to mean “and/of” unless explicitly indicated to refer to alternatives only or if the alternatives are mutually exclusive.

According to an exemplary aspect, the piezoelectric layer can be a thin single-crystal layer of a piezoelectric material, such as lithium niobate, lithium tantalate, lanthanum gallium silicate, gallium nitride, or aluminum nitride. It should be appreciated that the term “single-crystal” does not necessarily mean entirely of a uniform crystalline structure and may include impurities due to manufacturing variances as long as the crystal structure is within acceptable tolerances. The piezoelectric layer is cut such that the orientation of the X, Y, and Z crystalline axes with respect to the front and back sides is known and consistent. In the examples described herein, the piezoelectric layers are Z-cut, which is to say the Z axis is normal to the front and back sides 112, 114. However, XBARs may be fabricated on piezoelectric layers with other crystallographic orientations including rotated Z-cut, Y-cut and rotated YX cut.

The Y-cut family, such as 120Y and 128Y, are typically referred to as 120YX or 128YX, where the “cut angle” is the angle between the y axis and the normal to the layer. The “cut angle” is equal to β+90°. For example, a layer with Euler angles [0°, 30°, 0° ] is commonly referred to as “120° rotated Y-cut” or “120Y.” Thus, the Euler angles for 120YX and 128YX are (0, 120-90,0) and (0, 128-90,0) respectively. A “Z-cut” is typically referred to as a ZY cut and is understood to mean that the layer surface is normal to the Z axis but the wave travels along the Y axis. The Euler angles for ZY cut are (0, 0, 90).

The back side 114 of the piezoelectric layer 110 may be at least partially supported by a surface of the substrate 120 except for a portion of the piezoelectric layer 110 that forms a diaphragm 115 that is over (e.g., spanning or extending over) a cavity 140 in one or more layers below the piezoelectric layer 110 such as one or more intermediate layers above or in the substrate. In other words, the back side 114 of the piezoelectric layer 110 can be coupled or connected either directly or indirectly, via one or more intermediate layers (e.g., a dielectric layer, such as a silicon oxide layer), to a surface of the substrate 120. Moreover, the phrase “supported by” or “attached” may, as used herein interchangeably, mean attached directly, attached indirectly, mechanically supported, structurally supported, or any combination thereof. The portion of the piezoelectric layer that is over (e.g., spanning or extending over) the cavity can be referred to herein as a “diaphragm” 115 due to its physical resemblance to the diaphragm of a microphone. As shown in FIG. 1A, the diaphragm 115 is contiguous with the rest of the piezoelectric layer 110 around all of a perimeter 145 of the cavity 140. In this context, “contiguous” means “continuously connected without any intervening item”. However, the diaphragm 115 can be configured with at least 50% of the edge surface of the diaphragm 115 coupled to the edge of the piezoelectric layer 110 in an exemplary aspect.

According to the exemplary aspect, the substrate 120 is configured to provide mechanical support to the piezoelectric layer 110. The substrate 120 may be, for example, silicon, sapphire, quartz, or some other material or combination of materials. The back side 114 of the piezoelectric layer 110 may be bonded to the substrate 120 using a wafer bonding process. Alternatively, the piezoelectric layer 110 may be grown on the substrate 120 or supported by, or attached to, the substrate in some other manner.

For purposes of this disclosure, “cavity” has its conventional meaning of “an empty space within a solid body.” The cavity 140 may be a hole completely through the substrate 120 (as shown in Section A-A), a hole within a dielectric layer (as shown in FIG. 1B), or a recess in the substrate 120. The cavity 140 may be formed, for example, by selective etching of the substrate 120 before or after the piezoelectric layer 110 and the substrate 120 are attached, either directly or indirectly.

As shown, the conductor pattern of the XBAR 100 includes an interdigital transducer (IDT) 130. The IDT 130 includes a first plurality of parallel fingers, such as finger 136, extending from a first busbar 132 and a second plurality of fingers extending from a second busbar 134. The first and second pluralities of parallel fingers are interleaved with each other that can be “substantially” parallel to each other due to minor variations, such as due to manufacturing tolerances, for example. At least a portion of the interleaved fingers overlap for a distance AP, commonly referred to as the “aperture” of the IDT. The center-to-center distance L between the outermost fingers of the IDT 130 is the “length” of the IDT.

In the example of FIG. 1A, the IDT 130 is at the surface of the front side 112 (e.g., the first surface) of the piezoelectric layer 110. However, as discussed below, in other configurations, the IDT 130 may be at the surface of the back side 114 (e.g., the second surface) of the piezoelectric layer 110 or at both the surfaces of the front and back sides 112, 114 of the piezoelectric layer 110, respectively.

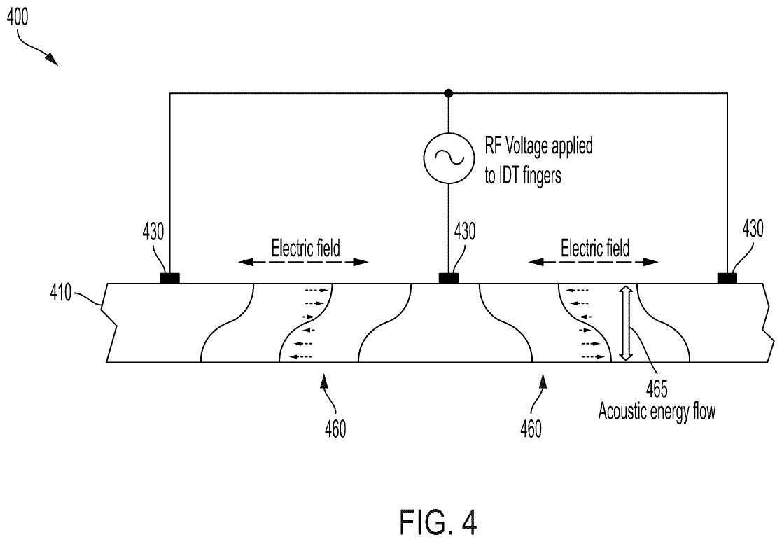

The first and second busbars 132, 134 are configured as the terminals of the XBAR 100 with the plurality of interleaved fingers extending therefrom. In operation, a radio frequency signal or microwave signal applied between the two busbars 132, 134 of the IDT 130 primarily excites an acoustic mode (i.e., a primarily shear acoustic mode) within the piezoelectric layer 110. As will be discussed in further detail, the primarily excited shear acoustic mode is a bulk shear mode or bulk acoustic wave where acoustic energy of a bulk shear acoustic wave is excited in the piezoelectric layer 110 by the IDT 130 and propagates along a direction substantially, predominantly, and/or primarily orthogonal to the surface of the piezoelectric layer 110, which is also primarily normal, or transverse, to the direction of the electric field created by the IDT fingers. That is, when a radio frequency or a microwave signal is applied between the two busbars 132, 134, the RF voltage applied to the respective sets of IDT fingers generates a time-varying electric field that is laterally excited with respect to a surface of the piezoelectric layer 110. Thus, in some cases the primarily excited acoustic mode may be commonly referred to as a laterally excited bulk acoustic wave since displacement, as opposed to propagation, occurs primarily in the direction of the bulk of the piezoelectric layer, as discussed in more detail below in reference to FIG. 4

For purposes of this disclosure, “primarily acoustic mode” may generally refer to an operational mode in which a vibration displacement is caused in the primarily thickness-shear direction (e.g., X-direction), so the wave propagates substantially and/or primarily in the direction connecting the opposing front and back surfaces of the piezoelectric layer, that is, in the Z direction. In other words, the X-direction component of the wave is significantly smaller than the Z-direction component. The use of the term “primarily” in the “primarily excited acoustic mode” is not necessarily referring to a lower or higher order mode. Thus, the XBAR is considered a transversely excited film bulk wave resonator. One physical constraint is that when the radio frequency or microwave signal is applied between the two busbars 132, 134 of the IDT 130, heat is generated that must be dissipated from the resonator for improved performance. In general, heat can be dissipated by lateral conduction on the membrane (e.g., in the electrodes themselves), and vertical conduction through a cavity to substrate.

In any event, the IDT 130 is positioned at or on the piezoelectric layer 110 such that at least the fingers of the IDT extend at or on the portion of the piezoelectric layer 110 that is over the cavity 140, for example, the diaphragm 115 as described herein. As shown in FIG. 1A, the cavity 140 has a rectangular cross section with an extent greater than the aperture AP and length L of the IDT 130. According to other exemplary aspects, the cavity of an XBAR may have a different cross-sectional shape, such as a regular or irregular polygon. The cavity of an XBAR may have more or fewer than four sides, which may be straight or curved.

According to an exemplary aspect, the area of XBAR 100 is determined as the area of the IDT 130. For example, the area of the IDT 130 can be determined based on the measurement of the length L multiplied by the width of the aperture AP of the interleaved fingers of the IDT 130. As used herein through the disclosure, area is referenced in μm². Thus, the area of the XBAR 100 may be adjusted based on design choices, as described below, thereby adjusting the overall capacitance of the XBAR 100.

For ease of presentation in FIG. 1A, the geometric pitch and width of the IDT fingers is greatly exaggerated with respect to the length (dimension L) and aperture (dimension AP) of the XBAR. A typical XBAR has more than ten parallel fingers in the IDT. For example, an XBAR may have hundreds, possibly thousands, of parallel fingers in the IDT according to exemplary aspects. Similarly, the thickness of the fingers in the cross-sectional views is greatly exaggerated.

FIG. 1B shows a schematic cross-sectional view of an alternative XBAR configuration 100′. In FIG. 1B, the cavity 140 (which can correspond generally to cavity 140 of FIG. 1A) of the resonator 100′ is formed entirely within a dielectric layer 124 (for example silicon oxide or silicon dioxide, as in FIG. 1B) that is located between the substrate 120 (indicated as Si in FIG. 1B) and the piezoelectric layer 110 (indicated as LN in FIG. 1B). Although a single dielectric layer 124 is shown having cavity 140 formed therein (e.g., by etching), it should be appreciated that the dielectric layer 124 can be formed by a plurality of separate dielectric layers formed on each other to provide a stack of materials.

Moreover, in the example of FIG. 1B, the cavity 140 is defined on all sides by the dielectric layer 124. However, in other exemplary embodiments, one or more sides of the cavity 140 may be defined by the substrate 120 and/or the piezoelectric layer 110. In the example of FIG. 1B, the cavity 140 has a trapezoidal shape. However, as noted above, cavity shape is not limited and may be rectangular, oval, or other shapes.

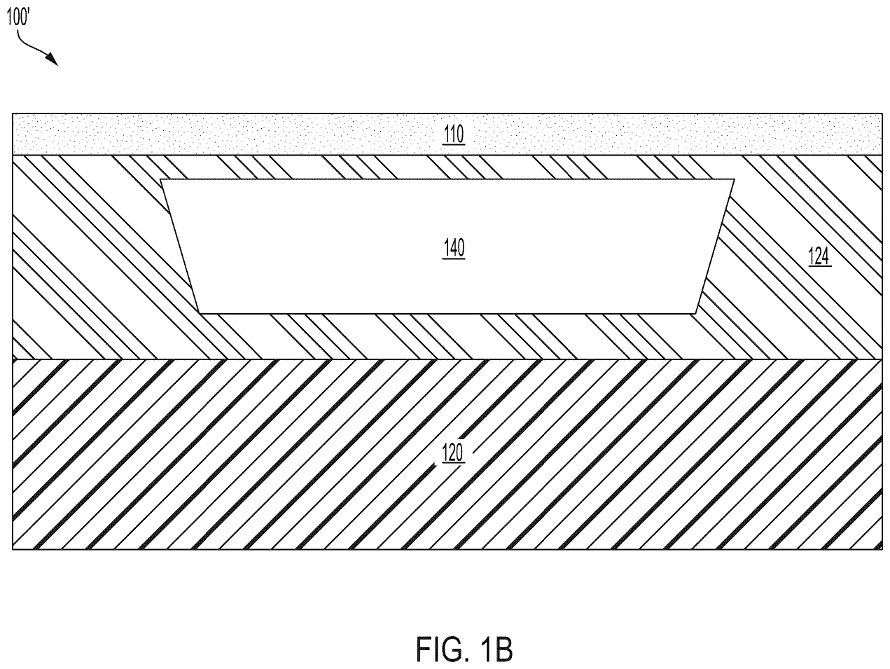

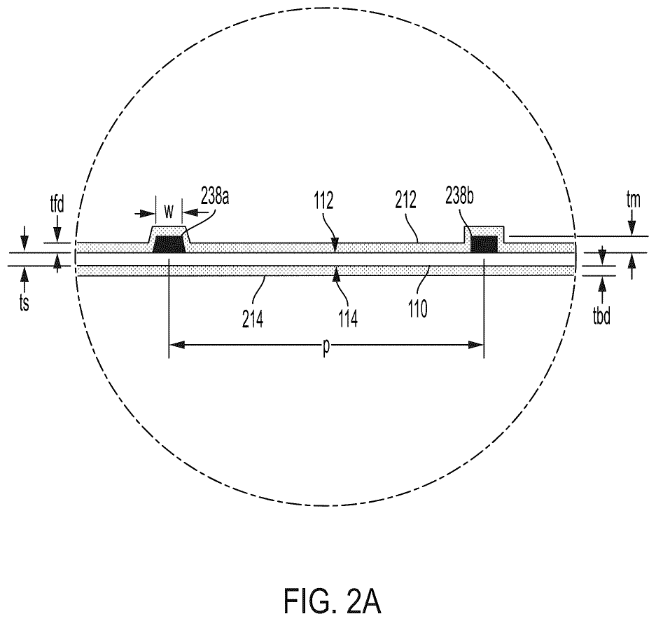

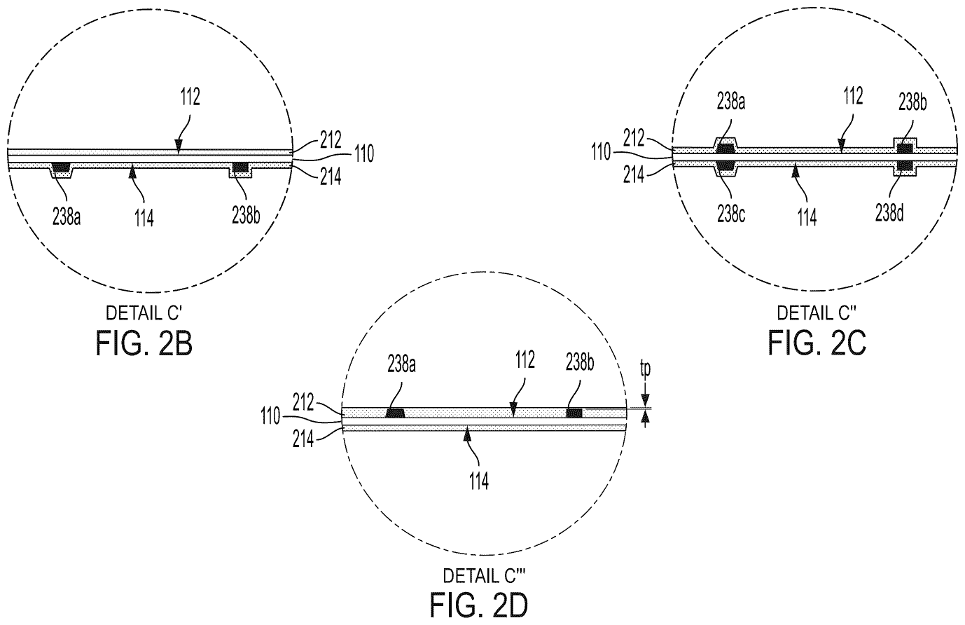

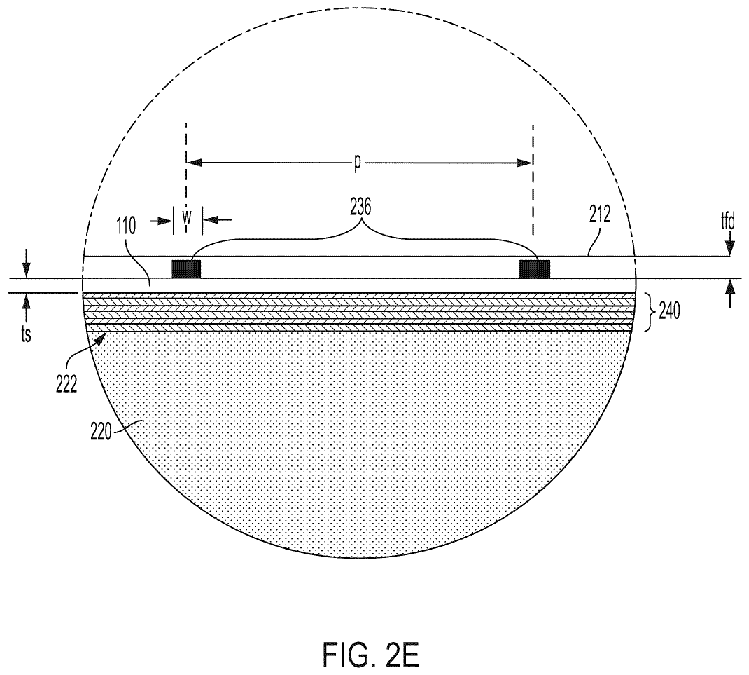

FIG. 2A shows a detailed schematic cross-sectional view (labeled as Detail C) of the XBAR 100 of FIG. 1A or 1B. The piezoelectric layer 110 is a single-crystal layer of piezoelectrical material having a thickness ts. Ts may be, for example, 100 nanometers (nm) to 1500 nm. When used in filters for 5G NR and Wi-Fi™ bands from 3.4 GHZ to 7 GHz, the thickness ts may be, for example, 150 nm to 500 nm. The thickness ts can be measured in a direction substantially perpendicular or orthogonal to a surface of the piezoelectric layer in an exemplary aspect.

In this aspect, a front side dielectric layer 212 (e.g., a first dielectric coating layer or material) can be formed on the front side 112 of the piezoelectric layer 110. The “front side” of the XBAR is, by definition, the surface facing away from the substrate. The front side dielectric layer 212 has a thickness tfd. As shown in FIG. 2A the front side dielectric layer 212 covers the IDT fingers 238a, 238b, which can correspond to fingers 136 as described above with respect to FIG. 1A. Although not shown in FIG. 2A, the front side dielectric layer 212 may also be deposited only between the IDT fingers 238a, 238b. In this case, an additional thin dielectric layer (not shown) may be deposited over the IDT fingers to seal and passivate the fingers. Further, although also not shown in FIG. 2A, the front side dielectric layer 212 may also be deposited only on select IDT fingers 238a, for example.

A back side dielectric layer 214 (e.g., a second dielectric coating layer or material) can also be formed on the back side of the back side 114 of the piezoelectric layer 110. In general, for purposes of this disclosure, the term “back side” means on a side opposite the conductor pattern of the IDT structure and/or opposite the front side dielectric layer 212. Moreover, the back side dielectric layer 214 has a thickness tbd. The front side and back side dielectric layers 212, 214 may be a non-piezoelectric dielectric material, such as silicon oxide, silicon dioxide or silicon nitride. Tfd and tbd may be, for example, 0 to 500 nm. Tfd and tbd may be less than the thickness ts of the piezoelectric layer. Tfd and tbd are not necessarily equal, and the front side and back side dielectric layers 212, 214 are not necessarily the same material. In exemplary aspects, either or both of the front side and back side dielectric layers 212, 214 may be formed of multiple layers of two or more materials according to various exemplary aspects.

The IDT fingers 238a, 238b may comprise aluminum, substantially (i.e., predominantly) aluminum alloys, copper, substantially (i.e., predominantly) copper alloys, beryllium, gold, or some other conductive material. Thin (relative to the total thickness of the conductors) layers of other metals, such as chromium or titanium, may be formed under and/or over the fingers to improve adhesion between the fingers and the piezoelectric layer 110 and/or to passivate or encapsulate the fingers. The busbars (132, 134 in FIG. 1A) of the IDT may be made of the same or different materials as the fingers. The cross-sectional shape of the IDT fingers may be trapezoidal (finger 238a), rectangular (finger 238b) or some other shape in various exemplary aspects. In general, it is noted that the terms “comprise”, “have”, “include” and “contain” (and their variants) as used herein are open-ended linking verbs and allow the addition of other elements when used in a claim. Moreover, the use of the word “a” or “an” when used in conjunction with the term “comprising” in the claims or the specification means one or more than one, unless the context dictates otherwise.

Dimension p (i.e., the “pitch”) can be considered the center-to-center spacing between adjacent IDT fingers, such as the IDT fingers 238a, 238b in FIGS. 2A-2D. Center points of center-to-center spacing may be measured at a center of the width “w” of a finger as shown in FIG. 2A. In some cases, the center-to-center spacing may change if the width of a given finger changes along the length of the finger, if the width and extending direction changes, or any variation thereof. In that case, for a given location along AP, center-to-center spacing may be measured as an average center-to-center spacing, a maximum center-to-center spacing, a minimum center-to-center spacing, or any variation thereof. Adjacent fingers may each extend from a different busbar and center-to-center spacing may be measured from a center of a first finger extending from a first busbar to a center of a second finger, adjacent to the first finger, extending from a second busbar. The center-to-center spacing may be constant over the length of the IDT, in which case the dimension p may be referred to as the pitch of the IDT and/or the pitch of the XBAR. However, in an alternative exemplary aspect, the center-to-center spacing varies along the length of the IDT, in which case the pitch of the IDT may be the average value of dimension p over the length of the IDT. Center-to-center spacing from one finger to an adjacent finger may vary continuously when compared to other adjacent fingers, in discrete sections of multiple adjacent pairs, or any combination thereof. Each IDT finger, such as the IDT fingers 238a, 238b in FIGS. 2A to 2D, has a width w measured normal to the long direction of each finger. The width w may also be referred to herein as the “mark.” In general, the width of the IDT fingers may be constant over the length of the IDT, in which case the dimension w may be the width of each IDT finger. However, in another exemplary aspect as will be discussed below, the width of individual IDT fingers varies along the length of the IDT 130, in which case dimension w may be the average value of the widths of the IDT fingers over the length of the IDT. Note that the pitch p and the width w of the IDT fingers are measured in a direction substantially parallel to the length L of the IDT, as defined in FIG. 1A.

In general, the IDT of an XBAR differs substantially from the IDTs used in surface acoustic wave (SAW) resonators, primarily in that IDTs of an XBAR excite a primary shear acoustic mode (also referred to as a primary shear mode, a primary shear thickness mode, or the like), as described in more detail below with respect to FIG. 4, where SAW resonators excite a surface wave in operation. Moreover, in a SAW resonator, the pitch of the IDT is one-half of the acoustic wavelength at the resonance frequency. Additionally, the mark-to-pitch ratio of a SAW resonator IDT is typically close to 0.5 (i.e., the mark or finger width is about one-fourth of the acoustic wavelength at resonance). In an XBAR, the pitch p of the IDT is typically 2 to 20 times the width w of the fingers. In addition, the pitch p of the IDT is typically 2 to 20 times the thickness ts of the piezoelectric layer 110. Moreover, the width of the IDT fingers in an XBAR is not constrained to one-fourth of the acoustic wavelength at resonance. For example, the width of XBAR IDT fingers may be 500 nm or greater, such that the IDT can be fabricated using optical lithography. The thickness tm of the IDT fingers may be from 100 nm to about equal to the width w, as the lithography process typically cannot support a configuration where the thickness is greater than the width. The thickness of the busbars (132, 134 in FIG. 1A) of the IDT may be the same as, less than, greater than, or any combination thereof, the thickness tm of the IDT fingers. It is noted that the XBAR devices described herein are not limited to the ranges of dimensions described herein.

Moreover, unlike a SAW filter, the resonance frequency of an XBAR is dependent on the total thickness of its diaphragm (i.e., in the vertical or thickness direction), including the piezoelectric layer 110, and the front side and back side dielectric layers 212, 214 disposed thereon. In an exemplary aspect, the thickness of one or both dielectric layers (i.e., on the opposing surfaces of the piezoelectric layer) can be varied to change the resonance frequencies of various XBARs in a filter. For example, shunt resonators in a ladder filter circuit may incorporate thicker dielectric layers to reduce the resonance frequencies of the shunt resonators relative to series resonators with thinner dielectric layers, and thus a thinner overall thickness.

Referring back to FIG. 2A, the thickness tfd of the front side dielectric layer 212 over the IDT fingers 238a, 238b may be greater than or equal to a minimum thickness required to cover and passivate the IDT fingers and other conductors on the front side 112 to the piezoelectric layer 110. The minimum thickness may be, for example, 10 nm to 50 nm depending on the material of the front side dielectric layer and method of deposition according to an exemplary aspect. The thickness of the back side dielectric layer 214 may be configured to a specific thickness to adjust the resonance frequency of the resonator as will be described in more detail below.

Although FIG. 2A discloses a configuration in which IDT fingers 238a and 238b are at the front side 112 of the piezoelectric layer 110, alternative configurations can be provided. For example, FIG. 2B shows an alternative configuration (identified as Detail C′) in which the IDT fingers 238a, 238b are at the back side 114 of the piezoelectric layer 110 (i.e., facing the cavity) and are covered by a back side dielectric layer 214. A front side dielectric layer 212 may cover the front side 112 of the piezoelectric layer 110. In exemplary aspects, a dielectric layer disposed on the diaphragm of each resonator can be trimmed or etched to adjust the resonant frequency. However, if the dielectric layer is on the side of the diaphragm facing the cavity, there may be a change in spurious modes (e.g., generated by the coating on the fingers). Moreover, with the passivation layer coated on top of the IDTs, the mark changes, which can also cause spurs. Therefore, disposing the IDT fingers 238a, 238b at the back side 114 of the piezoelectric layer 110 as shown in FIG. 2B may eliminate addressing both the change in frequency as well as the effect it has on spurs as compared when the IDT fingers 238a and 238b are on the front side 112 of the piezoelectric layer 110.

FIG. 2C shows an alternative configuration (identified as Detail C″) in which IDT fingers 238a, 238b are on the front side 112 of the piezoelectric layer 110 and are covered by a front side dielectric layer 212. IDT fingers 238c, 238d are also on the back side 114 of the piezoelectric layer 110 and are also covered by a back side dielectric layer 214. As previously described, the front side and back side dielectric layer 212, 214 are not necessarily the same thickness or the same material.

FIG. 2D shows another alternative configuration (identified as Detail C′″) in which IDT fingers 238a, 238b are on the front side 112 of the piezoelectric layer 110 and are covered by a front side dielectric layer 212. The surface of the front side dielectric layer is planarized. The front side dielectric layer may be planarized, for example, by polishing or some other method. A thin layer of dielectric material having a thickness tp may cover the IDT finger 238a, 238b to seal and passivate the fingers. The dimension TP may be, for example, 10 nm to 50 nm.

Each of the XBAR configurations described above with respect to FIGS. 2A to 2D include a diaphragm spanning over a cavity. However, in an alternative aspect, the bulk acoustic resonator can be solidly mounted in which the diaphragm with IDT fingers is mounted on or above a Bragg mirror, which in turn can be mounted on a substrate.

In particular, FIG. 2E shows a detailed schematic cross-sectional view of a solidly mounted XBAR (SM-XBAR). It is noted that FIG. 2E generally discloses a similar cross section as that of FIG. 1A, except having a solidly mounted configuration. In this aspect, the SM-XBAR includes a piezoelectric layer 110 and an IDT (of which only two fingers 236 are visible) with a dielectric layer 212 disposed on the piezoelectric layer 110 and IDT fingers 236. The piezoelectric layer 110 has parallel front and back surfaces similar to the configurations described above. Dimension ts is the thickness of the piezoelectric layer 110. The width of the IDT fingers 236 is dimension w, thickness of the IDT fingers is dimension tm, and the IDT pitch is dimension p.

In contrast to the XBAR devices shown in FIG. 1A, the IDT of an SM XBAR in FIG. 2E is not formed on a diaphragm spanning a cavity in the substrate. Instead, an acoustic Bragg reflector 240 is sandwiched between a surface 222 of the substrate 220 and the back surface of the piezoelectric layer 110. The term “sandwiched” means the acoustic Bragg reflector 240 is both disposed between and mechanically attached to a surface 222 of the substrate 220 and the back surface of the piezoelectric layer 110. In some circumstances, layers of additional materials (e.g., one or more dielectric layers) may be disposed between the acoustic Bragg reflector 240 and the surface 222 of the substrate 220 and/or between the Bragg reflector 240 and the back surface of the piezoelectric layer 110. Such additional material layers may be present, for example, to facilitate bonding the piezoelectric layer 110, the acoustic Bragg reflector 240, and the substrate 220.

The acoustic Bragg reflector 240 may be an acoustic mirror configured to reflect at least a portion of the primary acoustic mode excited in the piezoelectric and includes multiple dielectric layers that alternate between materials having high acoustic impedance and materials having low acoustic impedance. The acoustic impedance of a material is the product of the material's shear wave velocity and density. “High” and “low” are relative terms. For each layer, the standard for comparison is the adjacent layers. Each “high” acoustic impedance layer has an acoustic impedance higher than that of both the adjacent low acoustic impedance layers. Each “low” acoustic impedance layer has an acoustic impedance lower than that of both the adjacent high acoustic impedance layers. As discussed above, the primary acoustic mode in the piezoelectric layer of an XBAR is a shear bulk wave. In an exemplary aspect, each layer of the acoustic Bragg reflector 240 has a thickness equal to, or about, one-fourth of the wavelength in the layer of a shear bulk wave having the same polarization as the primary acoustic mode at or near a resonance frequency of the SM XBAR. Dielectric materials having comparatively low acoustic impedance include silicon dioxide, carbon-containing silicon oxide, and certain plastics such as cross-linked polyphenylene polymers. Materials having comparatively high acoustic impedance include hafnium oxide, silicon nitride, aluminum nitride, silicon carbide. All of the high acoustic impedance layers of the acoustic Bragg reflector 240 are not necessarily the same material, and all of the low acoustic impedance layers are not necessarily the same material. In the example of FIG. 2E, the acoustic Bragg reflector 240 has a total of six layers, but an acoustic Bragg reflector may have more than, or less than, six layers in alternative configurations.

The IDT fingers, such as IDT finger 236, 238a, and 238b, may be disposed on a surface of the front side 112 of the piezoelectric layer 110. Alternatively, IDT fingers, such as IDT finger 236, 238a, and 238b, may be disposed in grooves formed in the surface of the front side 112. The grooves may extend partially through the piezoelectric layer. Alternatively, the grooves may extend completely through the piezoelectric layer.

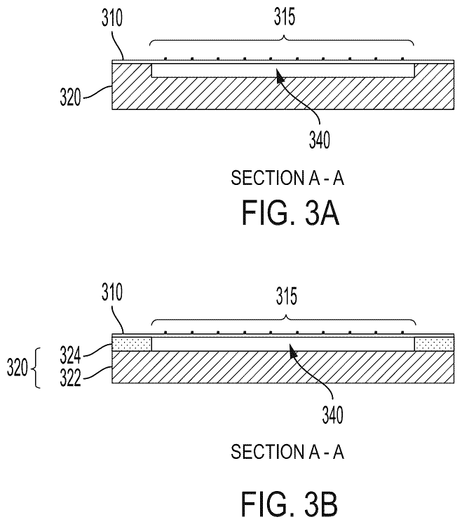

FIG. 3A and FIG. 3B show two exemplary cross-sectional views along the section plane A-A defined in FIG. 1A of XBAR 100. In FIG. 3A, a piezoelectric layer 310, which corresponds to piezoelectric layer 110, is attached directly to a substrate 320, which can correspond to substrate 120 of FIG. 1A. Moreover, a cavity 340, which does not fully penetrate the substrate 320, is formed in the substrate under the portion (i.e., the diaphragm 315) of the piezoelectric layer 310 containing the IDT of an XBAR. The cavity 340 can correspond to cavity 140 of FIGS. 1A and/or 1B in an exemplary aspect. In an exemplary aspect, the cavity 340 may be formed, for example, by etching the substrate 320 before attaching the piezoelectric layer 310. Alternatively, the cavity 340 may be formed by etching the substrate 320 with a selective etchant that reaches the substrate through one or more openings provided in the piezoelectric layer 310.

FIG. 3B illustrates an alternative aspect in which the substrate 320 includes a base 322 and an intermediate layer 324 that is disposed between the piezoelectric layer 310 and the base 322. For example, the base 322 may be silicon (e.g., a silicon support substrate) and the intermediate layer 324 may be silicon dioxide or silicon nitride or some other material, e.g., an intermediate dielectric layer. That is, in this aspect, the base 322 and the intermediate layer 324 are collectively considered the substrate 320. As further shown, cavity 340 is formed in the intermediate layer 324 under the portion (i.e., the diaphragm 315) of the piezoelectric layer 310 containing the IDT fingers of an XBAR. The cavity 340 may be formed, for example, by etching the intermediate layer 324 before attaching the piezoelectric layer 310. Alternatively, the cavity 340 may be formed by etching the intermediate layer 324. In other example embodiments, the cavity 340 may be defined in the intermediate layer 324 by other means from whether the intermediate layer 324 was etched to define the cavity 340. In some cases, the etching may be performed with a selective etchant that reaches the substrate through one or more openings (not shown) provided in the piezoelectric layer 310.

In this case, the diaphragm 315, which can correspond to diaphragm 115 of FIG. 1A, for example, in an exemplary aspect, may be contiguous with the rest of the piezoelectric layer 310 around a large portion of a perimeter of the cavity 340. For example, the diaphragm 315 may be contiguous with the rest of the piezoelectric layer 310 around at least 50% of the perimeter of the cavity 340. As shown in FIG. 3B, the cavity 340 extends completely through the intermediate layer 324. That is, the diaphragm 315 can have an outer edge that faces the piezoelectric layer 310 with at least 50% of the edge surface of the diaphragm 315 coupled to the edge of the piezoelectric layer 310 facing the diaphragm 315. This configuration provides for increased mechanical stability of the resonator.

In other configurations, the cavity 340 may partially extend into, but not entirely through the intermediate layer 324 (i.e., the intermediate layer 324 may extend over the bottom of the cavity on top of the base 322) or may extend through the intermediate layer 324 and into (either partially or wholly) the base 322. As described above, it should be appreciated that the interleaved fingers of the IDT can be disposed on either or both surfaces of the diaphragm 315 in FIGS. 3A and 3B according to various exemplary aspects.

FIG. 4 is a graphical illustration of the primarily excited acoustic mode of interest in an XBAR. FIG. 4 shows a small portion of an XBAR 400 including a piezoelectric layer 410 and three interleaved IDT fingers 430. In general, the exemplary configuration of XBAR 400 can correspond to any of the configurations described above and shown in FIGS. 2A to 2D according to an exemplary aspect. Thus, it should be appreciated that piezoelectric layer 410 can correspond to piezoelectric layer 110 and IDT fingers 430 can be implemented according to any of the configurations of fingers 238a and 238b, for example.

In operation, an RF voltage is applied to the interleaved fingers 430. This voltage creates a time-varying electric field between the fingers. The direction of the electric field is lateral (i.e., laterally excited), or primarily parallel to the surface of the piezoelectric layer 410, as indicated by the arrows labeled “electric field.” Due to the high dielectric constant of the piezoelectric layer 410, the electric field is highly concentrated in the piezoelectric layer relative to the air. The lateral electric field introduces shear deformation in the piezoelectric layer 410, and thus strongly excites a shear acoustic mode, in the piezoelectric layer 410. In this context, “shear deformation” is defined as deformation in which parallel planes in a material remain parallel and maintain a constant distance while translating relative to each other. In other words, the parallel planes of material are laterally displaced with respect to each other. A “shear acoustic mode” is defined as an acoustic vibration mode in a medium that results in shear deformation of the medium. The shear deformations in the XBAR 400 are represented by the curves 460, with the adjacent small arrows providing a schematic indication of the direction and magnitude of atomic motion. It is noted that the degree of atomic motion, as well as the thickness of the piezoelectric layer 410, have been exaggerated for ease of visualization in FIG. 4. While the atomic motions are predominantly lateral (i.e., horizontal as shown in FIG. 4), the direction of acoustic energy flow of the primarily excited shear acoustic mode is substantially and/or primarily orthogonal to the surface of the piezoelectric layer, as indicated by the arrow 465.

A bulk acoustic resonator based on shear acoustic wave resonances can achieve better performance than current state-of-the art film-bulk-acoustic-resonators (FBAR) and solidly-mounted-resonator bulk-acoustic-wave (SMR BAW) devices where the electric field is applied in the thickness direction. In such devices, the acoustic mode is compressive with atomic motions and the direction of acoustic energy flow in the thickness direction. In addition, the piezoelectric coupling for shear wave XBAR resonances can be high (>20%) compared to other acoustic resonators. Thus, high piezoelectric coupling enables the design and implementation of microwave and millimeter-wave filters with appreciable bandwidth.

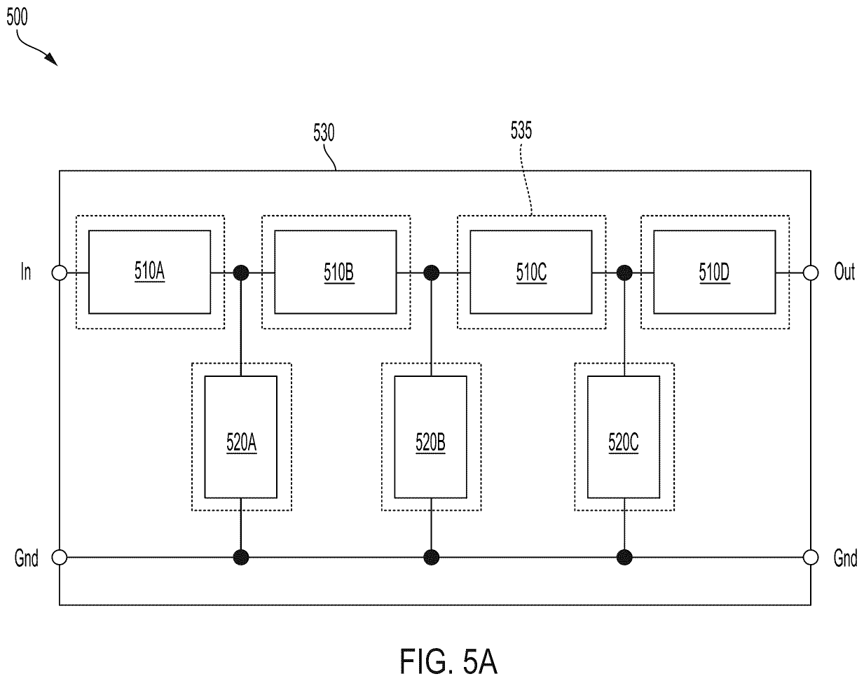

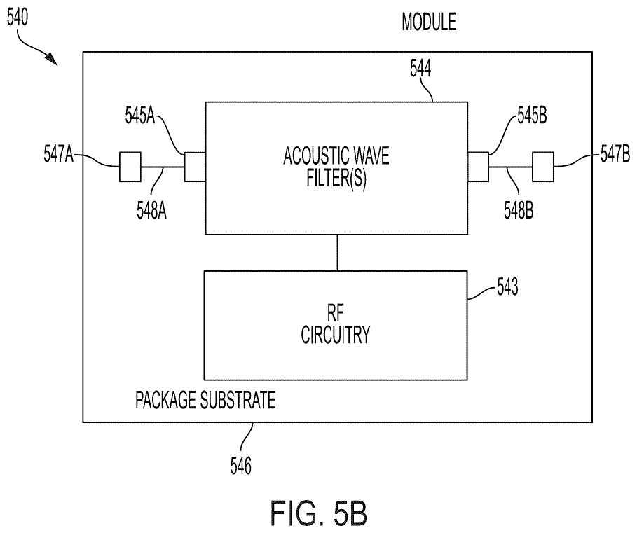

FIG. 5A is a schematic circuit diagram and layout for a high frequency bandpass filter 500 using XBARs, such as the general XBAR configuration 100 (e.g., the bulk acoustic resonators) described above, for example. The filter 500 has a conventional ladder filter architecture, which may include a split-ladder filter architecture wherein the filter is split between multiple chips, that has a plurality of bulk acoustic resonators including four resonators 510A, 510B, 510C, and 510D and three shunt resonators 520A, 520B and 520C. The series resonators 510A, 510B, 510C and 510D are connected in series between a first port and a second port (hence the term “series resonator”). In FIG. 5A, the first and second ports are labeled “In” and “Out”, respectively. However, the filter 500 is bidirectional and either port may serve as the input or output of the filter. At least two shunt resonators, such as the shunt resonators 520A and 520B, are connected from nodes between series resonators to a ground connection. A filter may contain additional reactive components, such as inductors, not shown in FIG. 5A. All the shunt resonators and series resonators are XBARs (e.g., either of the XBAR configurations 100 and/or 100′ as discussed above) in the exemplary aspect. The inclusion of four series and three shunt resonators is an example. A filter may have more or fewer than seven total resonators, more or fewer than four series resonators, and more or fewer than three shunt resonators. Typically, for a split ladder and non-split-ladder filter architectures, all of the series resonators are connected in series between an input and an output of the filter, and all of the shunt resonators are typically connected between ground and the input, the output, or a node between two series resonators.

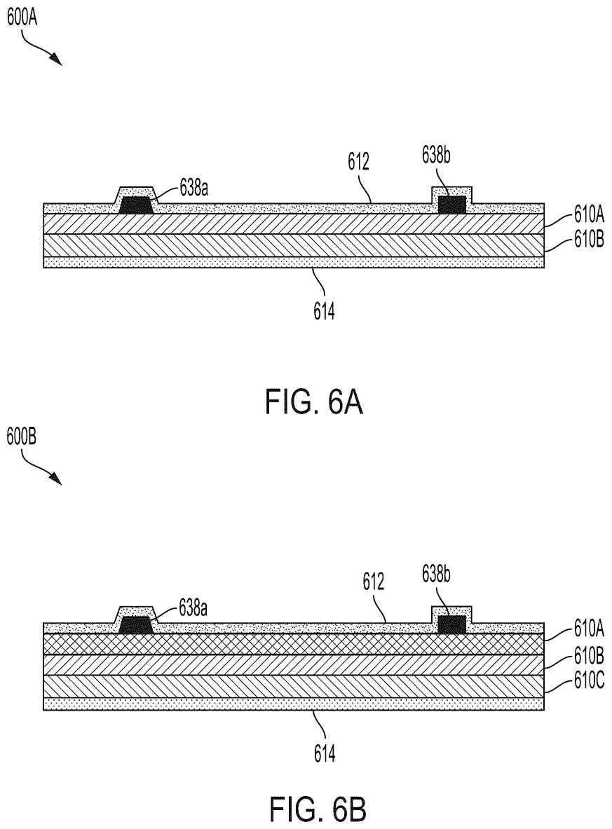

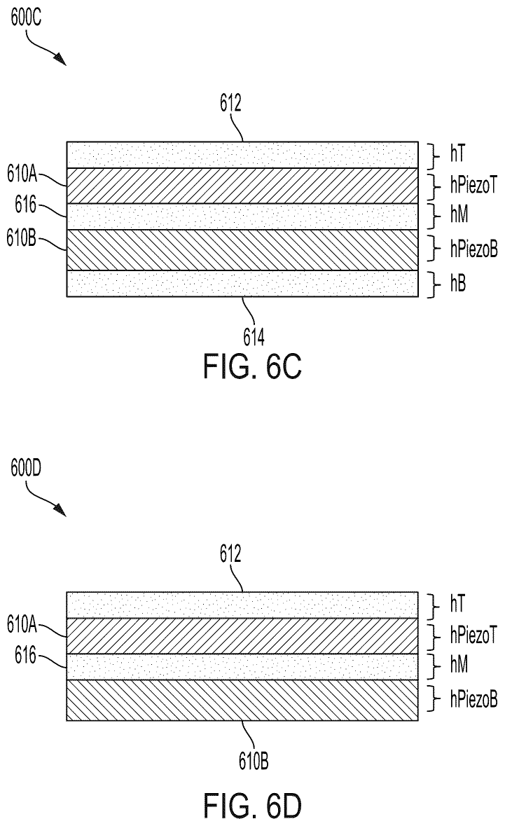

In the exemplary filter 500, the series resonators 510A, 510B, 510C and 510D and the shunt resonators 520A, 520B and 520C of the filter 500 can be formed on at least one, and in some cases a single, piezoelectric layer 530 of piezoelectric material bonded to a silicon substrate (not visible). However, in alternative aspects, the individual resonators may each be formed on a separate respective piezoelectric layer for each resonator wherein all resonators are located on the same chip. In either case, one or more of each the series and shunt resonators can also be formed to have the COP structure described below with respect to FIGS. 6A and 6B, for example. In some cases, however different resonators of a filter may be bonded to a separate substrate, for example. This may result in a split-ladder architecture that can include one or a plurality of separate chips that include separate piezoelectric layers and IDTs of one or more bulk acoustic resonators that are then configured together to form the overall split ladder filter. Moreover, each resonator includes a respective IDT (not shown), with at least the fingers of the IDT disposed over a cavity, or an acoustic mirror, in the substrate. In this and similar contexts, the term “respective” means “relating things each to each,” which is to say with a one-to-one correspondence. In FIG. 5A, the cavities are illustrated schematically as the dashed rectangles (such as the rectangle 535). In this example, each IDT is disposed over a respective cavity. In other filters, the IDTs of two or more resonators may be disposed over a single cavity.

Each of the resonators 510A, 510B, 510C, 510D, 520A, 520B and 520C in the filter 500 has a resonance where the admittance (also interchangeably referred to as Y-parameter) of the resonator is very high and an anti-resonance where the admittance of the resonator is very low. The resonance and anti-resonance occur at a resonance frequency and an anti-resonance frequency, respectively, which may be the same or different for the various resonators in the filter 500. In simplified terms, each resonator can be considered a short-circuit at its resonance frequency and an open circuit at its anti-resonance frequency. The input-output transfer function will be near zero at the resonance frequencies of the shunt resonators and at the anti-resonance frequencies of the series resonators. In a typical filter, the resonance frequencies of the shunt resonators are positioned below the lower edge of the filter's passband and the anti-resonance frequencies of the series resonators are positioned above the upper edge of the passband.

The frequency range between resonance and anti-resonance frequencies of a resonator corresponds to the coupling of the resonator. Depending on the design parameters of the filter 500, each of the resonators 510A, 510B, 510C, 510D, 520A, 520B and 520C may have a particular coupling parameter to which the respective resonator is tuned in order to achieve the required frequency response of the filter 500.

According to an exemplary aspect, each of the series resonators 510A, 510B, 510C and 510D and the shunt resonators 520A, 520B and 520C can have an XBAR configuration as described above with respect to FIGS. 1A-2D in which a diaphragm with IDT fingers spans over a cavity. Alternatively, each of the series resonators 510A, 510B, 510C, 510D and the shunt resonators 520A, 520B, and 520C can have an XBAR configuration in which the series resonators 510A, 510B, 510C, 510D and/or the shunt resonators 520A, 520B, and 520C can be solidly mounted on or above a Bragg mirror (e.g., as shown in FIG. 2E), which in turn can be mounted on a substrate. In either case, each of the series resonators 510A, 510B, 510C and 510D and the shunt resonators 520A, 520B and 520C can also have the COP structure of configuration of FIGS. 6A and 6B as will be discussed below.

FIG. 5B is a schematic diagram of a radio frequency module that includes an acoustic wave filter device according to an exemplary aspect. In particular, FIG. 5B illustrate a radio frequency module 540 that includes one or more acoustic wave filters 544 according to an exemplary aspect. The illustrated radio frequency module 540 also includes radio frequency (RF) circuitry (or RF circuit) 543. In an exemplary aspect, the acoustic wave filters 544 may include one or more of filter 500 including XBARs (e.g., the bulk acoustic resonators described herein), as described above with respect to FIG. 5A. In an exemplary aspect, the acoustic wave filters 544 may include one or more of filter 500 including XBARs, as described above with respect to FIG. 5A. In an exemplary aspect, the acoustic wave filter 544 may include one or more acoustic wave resonators with a COP structure and configuration of FIGS. 6A and 6B as will be discussed below.

The acoustic wave filter 544 shown in FIG. 5B includes terminals 545A and 545B (e.g., first and second terminals). The terminals 545A and 545B can serve, for example, as an input contact and an output contact for the acoustic wave filter 544. Although two terminals are illustrated, any suitable number of terminals can be implemented for a particular application. The acoustic wave filter 544 and the RF circuitry 543 are on a package substrate 546 (e.g., a common substrate) in FIG. 5B. The package substrate 546 can be a laminate substrate. The terminals 545A and 545B can be electrically connected to contacts 547A and 547B, respectively, on the package substrate 546 by way of electrical connectors 548A and 548B, respectively. The electrical connectors 548A and 548B can be bumps or wire bonds, for example. In an exemplary aspect, the acoustic wave filter 544 and the RF circuitry 543 may be enclosed together within a common package, with or without using the package substrate 546.

The RF circuitry 543 can include any suitable RF circuitry. For example, the RF circuitry can include one or more radio frequency amplifiers (e.g., one or more power amplifiers and/or one or more low noise amplifiers), one or more radio frequency switches, one or more additional RF filters, one or more RF couplers, one or more delay lines, one or more phase shifters, or any suitable combination thereof. The RF circuitry 543 can be electrically connected to the one or more acoustic wave filters 544. The radio frequency module 540 can include one or more packaging structures to, for example, provide protection and/or facilitate easier handling of the radio frequency module 540. Such a packaging structure can include an overmold structure formed over the package substrate 546. The overmold structure can encapsulate some or all of the components of the radio frequency module 540.

According to an exemplary aspect of the acoustic resonators (XBARs) described herein, the atomic motions of the XBAR configurations are predominantly lateral (i.e., horizontal as shown in FIG. 4) where the direction of acoustic energy flow is substantially orthogonal to the surface (or surfaces) of the piezoelectric layer. Moreover, the XBAR configurations can be configured to operate in any suitable acoustic wave mode based on the resonant frequency, for example. Example acoustic wave modes include the lowest order asymmetric (A₀) mode, the lowest order symmetric (S₀) mode, the first order asymmetric (A₁) mode, the first order symmetric (S₁) mode, the second order asymmetric (A₂) mode, the second order symmetric (S₂) mode, the third order asymmetric (A₃) mode, the third order symmetric (S₃) mode, and so forth.

In general, the symmetrical and antisymmetric zero order modes have ideal frequencies of zero, and, therefore, they are the only modes that exist over the entire frequency spectrum from zero to indefinitely high frequencies. In the low frequency range (i.e., when the wavelength is greater than the plate thickness) these modes are often called the “extensional mode” and the “flexural mode” respectively, to describe the nature of the motion and the elastic stiffnesses that govern the velocities of propagation. As the frequency of the resonator increases, the higher order wave modes occur in addition to the zero order modes. Each higher order mode starts at a resonant frequency of the plate and exists only above that frequency.

Currently, it is seen that conventional thickness scaling of A₁ mode applied for lower frequencies is no longer practical for higher frequencies (and high frequency filters) where the plate thickness becomes too thin (e.g., less than 150 nm) and the frequency sensitivity becomes too large. That is, increasing the mode order reduces the percentage frequency sensitivity by 1/n, where n is the mode order. Therefore, higher order modes can be used to help scale towards the higher frequency bands, but the increase in modes also leads to reduced electromechanical coupling k² as generated charges cancel out.

In view of these constraints, a multi-layer complementarily oriented piezoelectric (“COP”) structure with dielectric coating is implemented according to an exemplary aspect to achieve high coupling for higher order modes, such as the A₃ mode. As described in detail below, a COP structure includes a bonding of piezoelectric materials (e.g., layers or plates) with complementary cuts and/or crystallographic orientations. That is, these piezoelectric layers have a different crystallographic orientation with respect to each other such that the corresponding piezoelectric tensor has opposite polarity within the additional one or more COP layers. Moreover, in an exemplary aspect, a thin bonding layer (not shown) may also be disposed between piezoelectric layers 610A and 610B to facilitate bonding to one another as would be appreciated to one skilled in the art. The thin bond layer can be a dielectric layer (e.g., silicon oxide or silicon dioxide).

Although the exemplary aspect provides for a COP structure with two piezoelectric layers, it is noted that the number of piezoelectric layers within the COP structure is not limited to two layers in alternative aspects. In particular, the number of piezoelectric layers can be determined based on mode order and the required coupling k². In other words, high mode orders can be configured by increasing the number of COP layers, for example. Moreover, to further increase electromechanical coupling k² in higher order modes, such as the A₃ mode, a thickness of dielectric coupling can be provided on the acoustic resonator structure.

FIG. 6A is a schematic cross-sectional view of an acoustic wave resonator with a complementarily oriented piezoelectric (“COP”) structure according to an exemplary aspect. As shown, an acoustic resonator (e.g., an XBAR) 600A includes a pair of piezoelectric layers 610A and 610B (e.g., piezoelectric plate). In this aspect, a first piezoelectric layer (e.g., piezoelectric layer 610A, which can be considered a COP layer) is formed of and includes a material (e.g., lithium niobate or lithium tantalate) with a first cut having a first crystallographic orientation. Moreover, a second piezoelectric layer (e.g., piezoelectric layer 610B, which can be considered a standard layer) is coupled to the first piezoelectric layer (e.g., piezoelectric layer 610A) and is formed of and includes a material (e.g., lithium niobate or lithium tantalate) with a second cut having a second crystallographic orientation. In an exemplary aspect, the first and second cuts are configured such that a piezoelectric tensor of the second piezoelectric layer 610B is an opposite polarity to a piezoelectric tensor of the fist piezoelectric layer 610A to increase the electromechanical coupling k² of the resonator.

In an exemplary aspect, the piezoelectric layer 610A and 610B may be, for example, a lithium niobate (LN) plate or a lithium tantalate (LT) plate. The crystal structure of LN and LT belongs to the 3m point group in that it exhibits three-fold rotation symmetry about the c-axis, commonly defined as the Z-axis. Moreover, the crystal structures of the 3m point group exhibit single-fold symmetry about the a/b-axis, commonly defined as the X/Y-axis. The materials (e.g., LN or LT) of the different piezoelectric layers 610A and 610B will have different Euler angles to define a cut of the material. For example, the Euler angle may be [0°, β, 0° ], which may be referred to as a “Y-cut”, where the “cut angle” is the angle between the y axis and the normal to the plate. The “cut angle” is equal to β+90°. For example, a plate with Euler angles [0°, 30°, 0° ] is commonly referred to as “120° rotated Y-cut”. Thus, in an exemplary aspect, a material of the first piezoelectric layer 610A is a 60° rotated Y-cut lithium tantalate and the material of a second piezoelectric layer 610B is 120° rotated Y-cut lithium tantalate. Effectively, these cuts are oriented so that the corresponding piezoelectric tensor has opposite polarity within additional COP layer (e.g., piezoelectric layer 610A). It should be appreciated that the first piezoelectric layer 610A should be considered a minus 60°, such that the crystallographic orientations of the respective piezoelectric layers 610A and 610B are rotated 180 degrees (or approximately 180 degrees) with respect to each other. As noted below, the term “approximately” takes into account minor fluctuations in the design (e.g., in the degree or angle) due to, for example, manufacturing variances.

Otherwise, the XBAR 600A has a similar configuration as described above with respect to any of the cavity-based resonators (e.g., XBARs shown in FIGS. 1A and 1B and 2A-D) and/or the SM XBAR of FIG. 2E. Thus, it should be appreciated that XBAR 600A, for example, can implement any of the IDT configurations shown in FIGS. 1A through 2E and described above. Moreover, similar to the exemplary aspects described above, the pitch p of the IDT of the COP structure can be typically 2 to 20 times the width w of the fingers. In addition, the pitch p of the IDT is typically 2 to 20 times the thickness ts of the resonator stack, which includes the COP structure (i.e., piezoelectric layers 610A and 610B) and the first dielectric layer 612 and second dielectric layer 614.

As shown in FIG. 6A, a first (e.g., front side) dielectric layer 612 (e.g., a first dielectric coating layer or material) can be formed on the front side of the piezoelectric layer 610A. The dielectric layer 612 covers the IDT fingers 638a, 638b, which can correspond to fingers 136 as described above with respect to FIG. 1A or fingers 238a and 238b as described with respect to FIGS. 2A-2E. According to the exemplary aspect, the dielectric coating layer 612 is conformal to the IDT fingers and has a thickness h_{T} that is measured from the surface of the piezoelectric layer 610A to the top surface of the dielectric coating layer 612. Since the dielectric coating layer 612 is conformal, it will have the same (or substantially the same due to manufacturing tolerances) thickness across the surface of the resonator. Alternatively, the dielectric coating layer 612 could be planarized.

As shown, the dielectric layer 612 may also be deposited only between the IDT fingers 638a, 638b. In this case, an additional thin dielectric layer (not shown) may be deposited over the IDT fingers to seal and passivate the fingers. According to an exemplary aspect, the first dielectric coating layer 612 can be formed to have a thickness that increases a coupling coefficient of the acoustic resonator 600A for resonating in the third order antisymmetric (A₃) mode.

In addition, a second (e.g., back side) dielectric layer 614 (e.g., a second dielectric coating layer or material) can also be formed on the back side of a back surface of the piezoelectric layer 610B. That is, the second dielectric coating layer is disposed over a surface of the second piezoelectric layer 610B that is opposite a side of the piezoelectric layer 610B that is coupled to the first piezoelectric layer 610A. According to the exemplary aspect, the dielectric coating layer 614 has a thickness h_{B} that is measured from the surface of the piezoelectric layer 610B to the opposing surface of the dielectric coating layer 614. In this aspect, the dielectric coating layer 614 is planarized.

The first and second dielectric layers 612 and 614 may be a non-piezoelectric dielectric material, such as silicon oxide, silicon dioxide or silicon nitride. Moreover, the dielectric layers 612 and 614 may be formed of multiple layers of two or more materials according to various exemplary aspects.

As described above with respect to the earlier embodiment, the IDT fingers 638a, 638b may be aluminum, substantially aluminum alloys, copper, substantially copper alloys, beryllium, gold, or some other conductive material. Thin (relative to the total thickness of the conductors) layers of other metals, such as chromium or titanium, may be formed under and/or over the fingers to improve adhesion between the fingers and the piezoelectric layer 610A and/or to passivate or encapsulate the fingers. Busbars of the IDT may be made of the same or different materials as the fingers. The cross-sectional shape of the IDT fingers may be trapezoidal (finger 638a), rectangular (finger 638b) or some other shape in various exemplary aspects.

According to the exemplary aspect, the first and second piezoelectric layers 610A and 610B and the IDT (e.g., fingers 638a and 638b) are configured such that radio frequency signals applied to the IDT excites a primary shear acoustic mode in the first and second piezoelectric layers 610A and 610B. Moreover, the first and second dielectric coating layers 612 and 614 each can be provided to have a thickness that is based on the largest net stress of the respective materials of the first and second piezoelectric layers 610A and 610B, when the primary shear acoustic mode is excited in the first and second piezoelectric layers 610A and 610B.

As noted above, XBAR 600A can have configuration similar to the cavity based XBAR of FIGS. 1A-1B and 2A-2D. Although not specifically shown in FIG. 6A, the resonator 600A can include a substrate that includes a base (e.g., base 322 of FIG. 3B) and an intermediate layer (e.g., intermediate layer 324 of FIG. 3B). In this aspect, each of the first and second piezoelectric layers 610A and 610B will include a portion that is over a cavity that extends at least partially in the intermediate layer (e.g., intermediate layer 324 of FIG. 3B) of the substrate (e.g., substrate 320 of FIG. 3B). As further described, for example, with respect to FIG. 2B, a surface of the first piezoelectric layer 610A can be the surface on which the IDT is disposed to face the cavity. In an exemplary aspect, a thin bonding layer (not shown) may also be disposed between piezoelectric layers 610A and 610B to facilitate bonding to one another as would be appreciated to one skilled in the art.

Moreover, the IDT can include a plurality of interleaved fingers. For example, the IDT can have a configuration in which a first busbar and a second busbar each extend in a first direction from a first end to a second end thereof. Moreover, a first plurality of electrode fingers can extend from the first busbar in a second direction towards the second busbar, with the second direction intersecting the first direction, and a second plurality of electrode fingers can extend from the second busbar in the second direction towards to the first busbar, such that the first and second plurality of electrode fingers form the plurality of interleaved fingers of the IDT. Such a configuration of interleaved fingers is described above with respect to FIG. 1A.

As also noted above, the COP structure of the exemplary XBAR can have more than two piezoelectric layers. For example, FIG. 6B is a schematic cross-sectional view of an acoustic wave resonator with a complementarily oriented piezoelectric (“COP”) structure according to another exemplary aspect. In general, the acoustic resonator 600B in FIG. 6B has a similar configuration as described above with respect to acoustic resonator 600A and the like reference numbers refer to the same components so the description will not be repeated herein.

However, as further shown, acoustic resonator 600B can include a third piezoelectric layer 610C (i.e., another or second COP layer) that is disposed on a surface of the second piezoelectric layer 610B opposite the first piezoelectric layer 610A. According to an exemplary aspect, the third piezoelectric layer 610C comprises a same material (e.g., lithium niobate or lithium tantalate) as the first piezoelectric layer 610A and is formed of a material having the first cut and the first crystallographic orientation. In addition, according to an exemplary aspect, the material of first piezoelectric layer 610A and third piezoelectric layer 610C each have first Euler angles and the material of second piezoelectric layer 610B can have second Euler angles that are rotated by 180° about at least one axis (e.g., the X-axis and/or Y-axis) relative to the material of the first and third piezoelectric layers 610A and 610C. As will be discussed in detail below, the COP configurations shown in FIGS. 6A and 6B increases electromechanical coupling k² for higher order modes of the acoustic resonators 600A and 600B.

As described herein, the COP structure of the exemplary XBAR can also have one or more dielectric layers (e.g., bonding layers) between the two piezoelectric layers. For example, FIG. 6C is a schematic cross-sectional view of an acoustic wave resonator 600C with a COP structure according to another exemplary aspect. In general, the acoustic resonator 600C in FIG. 6C has a similar configuration as described above with respect to acoustic resonator 600A and the like reference numbers refer to the same components so the description will not be repeated herein. However, as further shown, a dielectric layer 616 (e.g., a middle dielectric layer) having a thickness h_{M} is disposed between (e.g., sandwiched) the first piezoelectric layer 610A and the first piezoelectric layers 610B. As described above, a first dielectric layer 612 is disposed on first piezoelectric layer 610A and a second dielectric layer 614 is disposed on second piezoelectric layer 610B.

It is also noted that FIG. 6D is a schematic cross-sectional view of an acoustic wave resonator 600D with a COP structure according to another exemplary aspect. Acoustic wave resonator 600D has the same structure as acoustic wave resonator 600C, except that the bottom or second dielectric layer 614 is omitted.

In each of acoustic wave resonators 600C and 600D, the dielectric layers (e.g., layers 612, 614 and 616) the dielectric material may be silicon oxide or silicon dioxide, for example. Moreover, the piezoelectric layers 610A and 610B can have the same materials and crystallographic orientations as described above with respect to FIGS. 6A and 6B.

FIG. 7A illustrates a plurality of graphs for varying thickness of top and bottom dielectric coating layers for higher order symmetric and anti-symmetric modes of an acoustic resonator, such as that having the configuration in FIG. 2A and described above in that the resonator has a single piezoelectric layer. The graphs in FIG. 7A are simulated by finite element method (FEM) simulation techniques, for example. Each of the graphs illustrates an X axis for the ratio of the bottom coating thickness h_{B} (e.g., thickness of dielectric layer 214) to the thickness of the piezoelectric layer H_{Piezo} (e.g., thickness of piezoelectric layer 110). Similarly, the Y axis is the ratio of the top coating thickness h_{T} (e.g., thickness of dielectric layer 212) to the thickness of the piezoelectric layer H_{Piezo} (e.g., thickness of piezoelectric layer 110).

As described above, the coupling k² is reduced in the higher order modes since the charges cancel out. In these graphs, it is noted that the coupling k² is normalized when the bottom coating thickness h_{B} and the top coating thickness h_{T} are zero. The shaded region illustrates the increase in coupling k² at the different ratios for the different modes of the acoustic resonator. It should be appreciated that optimal thickness ratios for top and bottom dielectric coating layers can be determined by selecting coating thickness where net stress within the piezoelectric material is largest. However, the thicker coating that provides for higher k² also requires the use of high Q materials to prevent large loss. Moreover, it can be seen, for example, that the normalized coupling k² for A3 mode having thin coating dielectric layers can only realize a one-ninth (i.e., 0.11) coupling k² for the fundamental (A1) mode.

In contrast, FIG. 7B illustrates a plurality of graphs for varying thickness of top and bottom dielectric coating layers for higher order symmetric and anti-symmetric modes of an acoustic resonator 600A with the COP structure, such as that having the configuration in FIG. 6A and described above. The graphs in FIG. 7B are simulated by finite element method (FEM) simulation techniques, for example. In this example, each of the graphs in FIG. 7B illustrates an X axis for the ratio of the bottom coating thickness h_{B} (e.g., thickness of dielectric layer 614) to the thickness of the piezoelectric layer H_{Piezo} (e.g., combined thickness of piezoelectric layers 610A and 610B). Similarly, the Y axis is the ratio of the top coating thickness h_{T} (e.g., thickness of dielectric layer 612) to the thickness of the piezoelectric layer H_{Piezo}, which in this instance is the combined thickness of piezoelectric layers 610A and 610B.

As described above, the coupling k² is reduced in the higher order modes since the charges cancel out. In these graphs, it is noted that the coupling k² is normalized when the bottom coating thickness h_{B} and the top coating thickness h_{T} are zero at the A₁ mode. Again, it is also noted that the optimal thickness ratios for top and bottom dielectric coating layers where large coupling k² is obtained are determined by selecting dielectric coating layer thicknesses where net stress within the piezoelectric layers 610A and 610B is largest. However, as is shown comparing the graphs of FIG. 7A with those in FIG. 7B, the COP structure (e.g., described above with respect to FIG. 6A) provides for increased coupling k² for higher order modes, such as the third order antisymmetric (A₃), the fourth order symmetric (S₄), and the fifth order antisymmetric (A₅) modes, for example. As further shown, significant coupling is obtained for the A₃ mode, with a thin coating ratio, for example, less than 0.5 ratio of dielectric coating layer (either the first dielectric coating layer 612 and/or the second dielectric coating layer 614) to the thickness of the lithium niobate piezoelectric layers 610A and 610B. It is noted that in this aspect, the combined thickness of the piezoelectric layers is h_{Piezo}, where each layer 610A and 610B has the same thickness (e.g., h_{Piezo}/2). In an exemplary aspect as shown in FIG. 7B, a high coupling k² for operating in the A₃ mode is obtain when either ratio h_{T}/h_{Piezo} or h_{B}/h_{Piezo} is between approximately 0.15 and 1.0. Moreover, in an exemplary aspect as shown in FIG. 7B, a high coupling k² for operating in the S₂ mode is obtain when both ratio h_{T}/h_{Piezo} or h_{B}/h_{Piezo} is greater than 0.0 and less than approximately 0.6. It is also noted that for purposes of this disclosure, the term “approximately” takes into account minor fluctuations in the design due to, for example, manufacturing variances. Thus, according to exemplary aspects, when the ratio h_{T}/h_{Piezo} is between approximately 0.15 and 1.0, the thickness h_{B} will be very thin only for passivation. Similarly, when the ratio h_{B}/h_{Piezo} is between approximately 0.15 and 1.0, the thickness h_{T} will be very thin only for passivation. The ratios according to an exemplary aspect will be discussed in more detail below with respect to FIGS. 7D and 7E.

Moreover, in an exemplary aspect, the first and second dielectric coating layers 612 and 614 can be half-lambda dielectric layers on the respective front surface an back surfaces of the piezoelectric plates. In this aspect, a thickness of the half-lambda dielectric layer is defined as 0.15λ0,d≤2ts≤1.0λ0,d, where λ0,d is a wavelength of a fundamental shear bulk acoustic wave resonance in the half-lambda dielectric layer, and where the thickness of the half-lambda dielectric layer is measured in a direction normal to the surface of the substrate. As also noted above, ts is the thickness of the piezoelectrical material, which in this case is the COP structure (including piezoelectric layers 610A and 610B).

In another exemplary aspect as shown in FIG. 7B, a high coupling k² for operating in the S₄ mode is obtain when both ratio h_{T}/h_{Piezo} and h_{B}/h_{Piezo} are between approximately 0.4 and 0.8. As shown in the S4 k² plot, a high coupling is obtained for the S₄ mode providing these ratios for the first and second dielectric coating layers 612 and 614. It is noted that the ratios should be the same since the S₄ mode is a symmetric, whereas the ratios for the A₃ mode are inversely related since the mode is asymmetric.

It is also noted that during manufacture, the first and second dielectric coating layers 612 and 614 are provided on the COP structure by a deposition process, which may not result in an exact uniform thickness of the respective layers. Therefore, the respective thickness h_{T} and h_{B} are considered to be average thickness across the length of the IDT for purposes of this disclosure.

As described above, the piezoelectric layer 610A and 610B can be formed of LN or LT and thus have a crystal structure that belongs to the 3m point group in that it exhibits three-fold rotation symmetry about the c-axis, commonly defined as the Z-axis.

FIG. 7C illustrates an alternative representation of plurality of graphs shown in FIG. 7B for varying thickness of top and bottom dielectric coating layers for higher order symmetric and anti-symmetric modes of an acoustic resonator 600A with the COP structure, such as that having the configuration in FIG. 6A and described above. The graphs in FIG. 7C are simulated by finite element method (FEM) simulation techniques, for example. As described above, a COP structure with optimal coating ratios achieves a coupling coefficient large k² that is otherwise not obtainable with conventional structures utilizing A3 mode with small coating ratios. FIG. 7C highlights that coating ratios (from FIG. 7B) where the high coupling coefficient k² is obtained with that COP structure that is larger than a maximum coupling coefficient k² that can be obtained with conventional structure utilizing A3 mode with a thin dielectric coating.

FIG. 7D illustrates an alternative representation of a graph shown in FIG. 7B for varying thickness of top and bottom dielectric coating layers for a high coupling coefficient k² for operating in the A₃ mode. The graph in FIG. 7D are simulated by finite element method (FEM) simulation techniques, for example. FIG. 7E illustrates a graph fitting a curve to the region shown in FIG. 7D for coating ratio of the COP structure provided for the high coupling coefficient k² for operating in the A₃ mode. The graph in FIG. 7E is simulated by finite element method (FEM) simulation techniques, for example.

Again, it should be appreciated that the exemplary graphs are provided for a resonator having the COP structure, such as that having the configuration in FIG. 6A and described above and also utilizing A3 mode with a thin dielectric coating. According to the exemplary aspect, the bottom coating ratio (e.g., in the X axis) is between 0.15 and 1.0 for dielectric bottom coating thickness h_{B} to the combined piezoelectric thickness h_{Piezo}. In this aspect, if the ratio of thickness of the bottom coating (e.g., the ratio of the thickness h_{B} of the dielectric layer 614 to the combined piezoelectric thickness h_{Piezo}) is identified as “x”, then the ratio for the opposite (or top) coating (e.g., the ratio of the thickness h_{T} of the dielectric layer 612 to the combined piezoelectric thickness h_{Piezo}) will be identified as “y”. In this example, the opposite coating layer (e.g., y) will be significantly thinner and have a ratio defined as: 0≤y≤−0.35x²+1.23x−0.18. This equation is a represented by the line fitted to the upper portion of the region in FIG. 7D providing coupling coefficient k² and is shown in FIG. 7E. Thus, in this exemplary aspect, the ratio h_{B} to h_{Piezo} is defined as x to be between 0.15 and 1.0, whereas the ratio of h_{T} to h_{Piezo} is defined as y to be: 0≤y≤−0.35x²+1.23x−0.18. As shown in FIG. 7D, this configuration with these ranges of ratios provides for a significant improvement in the coupling coefficient k² compared with conventional structures. The dark region in FIG. 7D identifies coating ratios where a normalized coupling coefficient k² of the A3 mode with the exemplary COP structure described herein is greater than 1/9 obtained in the A3 mode.

It is noted that the opposite configuration can also be implemented as long as the ratios remain consistent. That is, the ratio h_{T} to h_{Piezo} can be defined as y to be between 0.15 and 1.0, whereas the ratio of h_{B} to h_{Piezo} is defined as x to be: 0≤x≤−0.35y²+1.23y−0.18. The same coupling coefficient k² will be obtained according to this alternative configuration.

FIG. 7F illustrates a plurality of graphs for varying thicknesses of top and bottom dielectric coating layers for higher order symmetric and anti-symmetric modes of an acoustic resonator 600B with the three layer COP structure, such as that having the configuration in FIG. 6B and described above. The graphs in FIG. 7F are simulated by finite element method (FEM) simulation techniques, for example, and it is assumed that the thickness of each piezoelectric layer 610A, 610B and 610C is the same as one another. Moreover, in this example, each of the graphs in FIG. 7F illustrates an X axis for the ratio of the bottom coating thickness h_{B} (e.g., thickness of dielectric layer 614) to the thickness of the piezoelectric layer H_{Piezo} (e.g., combined thickness of piezoelectric layers 610A, 610B, and 610C). Similarly, the Y axis is the ratio of the top coating thickness h_{T} (e.g., thickness of dielectric layer 612) to the thickness of the piezoelectric layer H_{Piezo}, which in this instance is the combined thickness of piezoelectric layers 610A, 610B and 610C.

As described above, the coupling k² is reduced in the higher order modes since the charges cancel out. In these graphs, it is noted that the coupling k² is normalized when the bottom coating thickness h_{B} and the top coating thickness h_{T} are zero at the A₁ mode. Again, it is also noted that the optimal thickness ratios for top and bottom dielectric coating layers where large coupling k² is obtained are determined by selecting dielectric coating layer thicknesses where net stress within the piezoelectric layers 610A, 610B and 610C is largest. However, as is shown in the graphs of FIG. 7F, the COP structure (e.g., described above with respect to FIG. 6B) provides for increased coupling k² for higher order modes, such as the third order antisymmetric (A₃), the fourth order symmetric (S₄), and the fifth order antisymmetric (A₅) modes, for example. As further shown, significant coupling is obtained for the A₃ mode, with a thin coating ratio, for example, less than 0.35 ratio of dielectric coating layer (both the first dielectric coating layer 612 and the second dielectric coating layer 614) to the thickness of the lithium niobate piezoelectric layers 610A, 610B and 610C. As noted above, the combined thickness of the piezoelectric layers is h_{Piezo}, where each layer 610A, 610B and 610C has the same thickness (e.g., h_{Piezo}/3). In an exemplary aspect as shown in FIG. 7F, a high coupling k² for operating in the A₃ mode is obtain when both ratios h_{T}/h_{Piezo} and h_{B}/h_{Piezo} are greater than 0.0 and less than approximately 0.35. Advantageously, providing an acoustic resonator having these ratios of dielectric coating layer thicknesses provides a coupling k² of at least 0.33 as shown in the plot for the A₃ mode.

FIG. 7G illustrates a plurality of graphs for varying thicknesses of top and sandwich dielectric coating layers for higher order symmetric and anti-symmetric modes of an acoustic resonator 600C with the COP sandwich structure (i.e., having a dielectric layer between two piezoelectric layers), such as that having the configuration in FIG. 6C and described above. The graphs in FIG. 7G are simulated by finite element method (FEM) simulation techniques, for example, and it is assumed that the thickness of each piezoelectric layer 610A and 610B is the same as one another. In this example, each of the graphs in FIG. 7G illustrates an X axis for the ratio of the sandwich coating thickness h_{S} (e.g., thickness h_{M} of dielectric layer 616) to the thickness of the piezoelectric layer H_{Piezo} (e.g., combined thickness of piezoelectric layers 610A and 610B). Similarly, the Y axis is the ratio of the top coating thickness h_{T} (e.g., thickness of dielectric layer 612) to the thickness of the piezoelectric layer H_{Piezo}, which again in this instance is the combined thickness of piezoelectric layers 610A and 610B. As shown in this instance, the spurious responses are entirely (or substantially) eliminated in the anti-resonance modes, A1, A3, A5 and A7. Moreover, as shown in FIG. 7G, a high coupling k² for operating in the S₂ mode is obtain when the ratio of h_{S}/h_{Piezo} is greater than 0.0 and less than approximately 0.5.

FIG. 7H illustrates a plurality of graphs for varying thicknesses of top and sandwich dielectric coating layers for higher order symmetric and anti-symmetric modes of an acoustic resonator 600D with the COP sandwich structure (i.e., having a dielectric layer between two piezoelectric layers), but without a bottom dielectric coating layer, such as that having the configuration in FIG. 6D and described above. The graphs in FIG. 7H are simulated by finite element method (FEM) simulation techniques, for example, and it is assumed that the thickness of each piezoelectric layer 610A and 610B is the same as one another. In this example, each of the plots in FIG. 7G illustrates an X axis for the ratio of the sandwich coating thickness h_{S} (e.g., thickness h_{M} of dielectric layer 616) to the thickness of the piezoelectric layer H_{Piezo} (e.g., combined thickness of piezoelectric layers 610A and 610B). Similarly, the Y axis is the ratio of the top coating thickness h_{T} (e.g., thickness of dielectric layer 612) to the thickness of the piezoelectric layer H_{Piezo}, which again in this instance is the combined thickness of piezoelectric layers 610A and 610B.

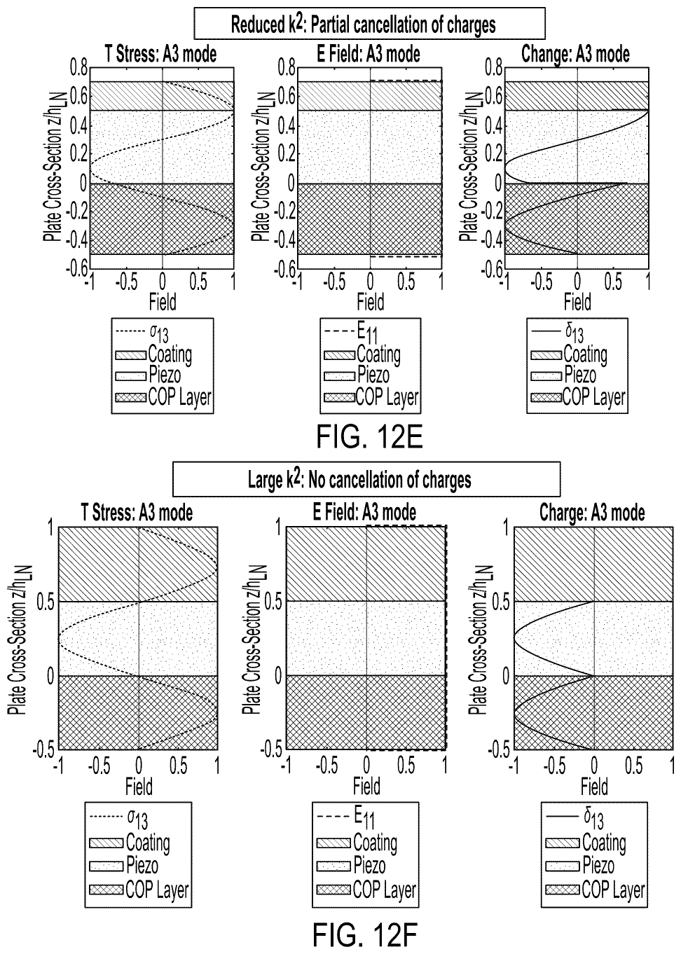

FIG. 71 illustrates an alternative representation of a graph shown in FIG. 7B for varying thickness of top and bottom dielectric coating layers for a high coupling coefficient k² for operating in the S₂ mode. The graph in FIG. 71 is simulated by finite element method (FEM) simulation techniques, for example. As further shown, a curve fitted to the region shown in FIG. 71 is provided for coating ratios of the COP structure provided for the high coupling coefficient k² for operating in the S₂ mode and having the configuration of the bulk acoustic resonator shown in FIG. 6A.

According to the exemplary aspect, the bulk acoustic resonator is configured to have a high coupling coefficient k² of greater than 0.50 and the curve is a least squares fit for an ellipse. In this example, the ratio of thickness of the bottom coating (e.g., the ratio of the thickness h_{B} of the dielectric layer 614 to the combined piezoelectric thickness h_{Piezo}) is identified as “x”, and the ratio for the opposite (or top) coating (e.g., the ratio of the thickness h_{T} of the dielectric layer 612 to the combined piezoelectric thickness h_{Piezo}) is be identified as “y”. Accordingly, the exemplary bulk acoustic resonator achieves the desired coupling coefficient k² of greater than 0.50 when the respective ratios are in the dark region shown in FIG. 71, which can be defined by the equation:

$${ax}^{2} + bxy + {cy}^{2} + dy + ey - 1 \leq 0 ,$$

where: a=38.03, b=−35.26, c=38.03, d=−9.23 and e=−9.23.

It should also be appreciated that this equation is valid for coating ratios (i.e., top and bottom) between 0 and 1, as defined by the X and Y axes, respectively. In other words, a bulk acoustic resonator that has the defined thickness ratios x and y that satisfy the above-noted equation will advantageously provide a coupling coefficient k² of greater than 0.50 in the S₂ mode having the COP structure in FIG. 6A.

FIG. 7J illustrates an alternative representation of a graph shown in FIG. 7B for varying thickness of top and bottom dielectric coating layers for a high coupling coefficient k² for operating in the A₃ mode. The graph in FIG. 7J is simulated by finite element method (FEM) simulation techniques, for example. As further shown, a curve fitted to the two regions shown in FIG. 7J is provided for coating ratios of the COP structure provided for the high coupling coefficient k² for operating in the A₃ mode and having the configuration of the bulk acoustic resonator shown in FIG. 6A.

According to the exemplary aspect, the bulk acoustic resonator is configured to have a high coupling coefficient k² of greater than 0.33 and the curves are a least squares fit for an ellipse. In this example, the ratio of thickness of the bottom coating (e.g., the ratio of the thickness h_{B} of the dielectric layer 614 to the combined piezoelectric thickness h_{Piezo}) is identified as “x”, and the ratio for the opposite (or top) coating (e.g., the ratio of the thickness h_{T} of the dielectric layer 612 to the combined piezoelectric thickness h_{Piezo}) is be identified as “y”. Accordingly, the exemplary bulk acoustic resonator achieves the desired coupling coefficient k² of greater than 0.33 when the respective ratios are in the dark regions shown in FIG. 7J, which can be defined by the equations:

$${ax}^{2} + bxy + {cy}^{2} + dx + ey - 1 \geq 0 ,$$

where: a=−11.55, b=10.10, c=−3.83, d=−4.45 and e=4.81 (for the upper left region)
where: a=−3.83, b=10.10, c=−11.55, d=4.81 and e=−4.45 (for the lower right region).

It should also be appreciated that this equation is valid for coating ratios (i.e., top and bottom) between 0 and 1, as defined by the X and Y axes, respectively. In other words, a bulk acoustic resonator that has the defined thickness ratios x and y that satisfy the above-noted equation will advantageously provide a coupling coefficient k² of greater than 0.33 in the A₃ mode having the COP structure in FIG. 6A.

FIG. 7K illustrates an alternative representation of a graph shown in FIG. 7F for varying thickness of top and bottom dielectric coating layers for a high coupling coefficient k² for operating in the A₃ mode. The graph in FIG. 7K is simulated by finite element method (FEM) simulation techniques, for example. As further shown, a curve fitted to the region shown in FIG. 7K is provided for coating ratios of the COP structure provided for the high coupling coefficient k² for operating in the A₃ mode and having the configuration of the bulk acoustic resonator shown in FIG. 6B.

According to the exemplary aspect, the bulk acoustic resonator is configured to have a high coupling coefficient k² of greater than 0.33 and the curve is a least squares fit for an ellipse. In this example, the ratio of thickness of the bottom coating (e.g., the ratio of the thickness h_{B} of the dielectric layer 614 to the combined piezoelectric thickness h_{Piezo}) is identified as “x”, and the ratio for the opposite (or top) coating (e.g., the ratio of the thickness h_{T} of the dielectric layer 612 to the combined piezoelectric thickness h_{Piezo}) is be identified as “y”. Accordingly, the exemplary bulk acoustic resonator achieves the desired coupling coefficient k² of greater than 0.33 when the respective ratios are in the dark region shown in FIG. 7K, which can be defined by the equation:

$${ax}^{2} + bxy + {cy}^{2} + dx + ey - 1 \leq 0 ,$$

where: a=62.27, b=−50.33, c=62.27, d=−10.65 and e=−10.65.

It should also be appreciated that this equation is valid for coating ratios (i.e., top and bottom) between 0 and 1, as defined by the X and Y axes, respectively. In other words, a bulk acoustic resonator that has the defined thickness ratios x and y that satisfy the above-noted equation will advantageously provide a coupling coefficient k² of greater than 0.33 in the A₃ mode having the COP structure in FIG. 6B.

FIG. 7L illustrates an alternative representation of a graph shown in FIG. 7F for varying thickness of top and bottom dielectric coating layers for a high coupling coefficient k² for operating in the S₄ mode. The graph in FIG. 7L is simulated by finite element method (FEM) simulation techniques, for example. As further shown, a curve fitted to the two regions shown in FIG. 7L is provided for coating ratios of the COP structure provided for the high coupling coefficient k² for operating in the S₄ mode and having the configuration of the bulk acoustic resonator shown in FIG. 6B.

According to the exemplary aspect, the bulk acoustic resonator is configured to have a high coupling coefficient k² of greater than 0.25 and the curves are a least squares fit for an ellipse. In this example, the ratio of thickness of the bottom coating (e.g., the ratio of the thickness h_{B} of the dielectric layer 614 to the combined piezoelectric thickness h_{Piezo}) is identified as “x”, and the ratio for the opposite (or top) coating (e.g., the ratio of the thickness h_{T} of the dielectric layer 612 to the combined piezoelectric thickness h_{Piezo}) is be identified as “y”. Accordingly, the exemplary bulk acoustic resonator achieves the desired coupling coefficient k² of greater than 0.25 when the respective ratios are in the dark regions shown in FIG. 7L, which can be defined by the equations:

$${ax}^{2} + bxy + {cy}^{2} + dx + ey - 1 \geq 0 ,$$

where: a=−22.27, b=20.05, c=−9.79, d=−5.55 and e=7.99 (for the upper left region)
where: a=−9.79, b=20.05, c=−22.27, d=7.99 and e=−5.55 (for the lower right region).

It should also be appreciated that this equation is valid for coating ratios (i.e., top and bottom) between 0 and 1, as defined by the X and Y axes, respectively. In other words, a bulk acoustic resonator that has the defined thickness ratios x and y that satisfy the above-noted equation will advantageously provide a coupling coefficient k² of greater than 0.25 in the S₄ mode having the COP structure in FIG. 6B.

FIG. 7M illustrates an alternative representation of a graph shown in FIG. 7G for varying thickness of top and sandwich dielectric coating layers for a high coupling coefficient k² for operating in the S₂ mode. The graph in FIG. 7M is simulated by finite element method (FEM) simulation techniques, for example. As further shown, a curve fitted to the region shown in FIG. 7M is provided for coating ratios of the COP structure provided for the high coupling coefficient k² for operating in the S₂ mode and having the configuration of the bulk acoustic resonator shown in FIG. 6C.

According to the exemplary aspect, the bulk acoustic resonator is configured to have a high coupling coefficient k² of greater than 0.50 and the curve is a least squares fit for an ellipse. In this example, the ratio of thickness of the sandwich coating (e.g., the ratio of the thickness h_{S} of the dielectric layer 616 to the combined piezoelectric thickness h_{Piezo}) is identified as “x”, and the ratio for the opposite (or top) coating (e.g., the ratio of the thickness h_{T} of the dielectric layer 612 to the combined piezoelectric thickness h_{Piezo}) is be identified as “y”. Accordingly, the exemplary bulk acoustic resonator achieves the desired coupling coefficient k² of greater than 0.50 when the respective ratios are in the dark region shown in FIG. 7M, which can be defined by the equation:

$${ax}^{2} + bxy + {cy}^{2} + dx + ey - 1 \leq 0 ,$$

where: a=1.26, b=−0.75, c=2.45, d=−2.74 and e=−0.78.

It should also be appreciated that this equation is valid for coating ratios (i.e., top and bottom) between 0 and 1, as defined by the X and Y axes, respectively. In other words, a bulk acoustic resonator that has the defined thickness ratios x and y that satisfy the above-noted equation will advantageously provide a coupling coefficient k² of greater than 0.50 in the S₂ mode having the COP structure in FIG. 6C.

FIG. 7N illustrates an alternative representation of a graph shown in FIG. 7G for varying thickness of top and sandwich dielectric coating layers for a high coupling coefficient k² for operating in the S₄ mode. The graph in FIG. 7N is simulated by finite element method (FEM) simulation techniques, for example. As further shown, a curve fitted to the two regions shown in FIG. 7N is provided for coating ratios of the COP structure provided for the high coupling coefficient k² for operating in the S₄ mode and having the configuration of the bulk acoustic resonator shown in FIG. 6C.

According to the exemplary aspect, the bulk acoustic resonator is configured to have a high coupling coefficient k² of greater than 0.25 and the curves are a least squares fit for an ellipse. In this example, the ratio of thickness of the sandwich coating (e.g., the ratio of the thickness h_{S} of the dielectric layer 616 to the combined piezoelectric thickness h_{Piezo}) is identified as “x”, and the ratio for the opposite (or top) coating (e.g., the ratio of the thickness h_{T} of the dielectric layer 612 to the combined piezoelectric thickness h_{Piezo}) is be identified as “y”. Accordingly, the exemplary bulk acoustic resonator achieves the desired coupling coefficient k² of greater than 0.25 when the respective ratios are in the dark region shown in FIG. 7L, which can be defined by the equation:

$${ax}^{2} + bxy + {cy}^{2} + dx + ey - 1 \geq 0 ,$$

where: a=2.33, b=−12.77, c=9.28, d=−0.72 and e=1.42.

It should also be appreciated that this equation is valid for coating ratios (i.e., top and bottom) between 0 and 1, as defined by the X and Y axes, respectively. In other words, a bulk acoustic resonator that has the defined thickness ratios x and y that satisfy the above-noted equation will advantageously provide a coupling coefficient k² of greater than 0.25 in the S₄ mode having the COP structure in FIG. 6C.

FIG. 70 illustrates an alternative representation of a graph shown in FIG. 7H for varying thickness of top and sandwich dielectric coating layers for a high coupling coefficient k² for operating in the S₂ mode. The graph in FIG. 7O is simulated by finite element method (FEM) simulation techniques, for example. As further shown, a curve fitted to the region shown in FIG. 7O is provided for coating ratios of the COP structure provided for the high coupling coefficient k² for operating in the S₂ mode and having the configuration of the bulk acoustic resonator shown in FIG. 6D.

According to the exemplary aspect, the bulk acoustic resonator is configured to have a high coupling coefficient k² of greater than 0.50 and the curve is a least squares fit for an ellipse. In this example, the ratio of thickness of the sandwich coating (e.g., the ratio of the thickness h_{S} of the dielectric layer 616 to the combined piezoelectric thickness h_{Piezo}) is identified as “x”, and the ratio for the opposite (or top) coating (e.g., the ratio of the thickness h_{T} of the dielectric layer 612 to the combined piezoelectric thickness h_{Piezo}) is be identified as “y”. Accordingly, the exemplary bulk acoustic resonator achieves the desired coupling coefficient k² of greater than 0.50 when the respective ratios are in the dark region shown in FIG. 7O, which can be defined by the equation:

$${ax}^{2} + bxy + {cy}^{2} + dx + ey - 1 \leq 0 ,$$

where: a=4.47, b=−7.95, c=21.65, d=−3.07 and e=−4.01.

It should also be appreciated that this equation is valid for coating ratios (i.e., top and bottom) between 0 and 1, as defined by the X and Y axes, respectively. In other words, a bulk acoustic resonator that has the defined thickness ratios x and y that satisfy the above-noted equation will advantageously provide a coupling coefficient k² of greater than 0.50 in the S₂ mode having the COP structure in FIG. 6D.

FIG. 7P illustrates an alternative representation of a graph shown in FIG. 7H for varying thickness of top and sandwich dielectric coating layers for a high coupling coefficient k² for operating in the A₃ mode. The graph in FIG. 7P is simulated by finite element method (FEM) simulation techniques, for example. As further shown, a curve fitted to the region shown in FIG. 7P is provided for a coating ratio of the COP structure provided for the high coupling coefficient k² for operating in the A₃ mode and having the configuration of the bulk acoustic resonator shown in FIG. 6D.

According to the exemplary aspect, the bulk acoustic resonator is configured to have a high coupling coefficient k² of greater than 0.33 and the curves are a least squares fit for an ellipse. In this example, the ratio of thickness of the sandwich coating (e.g., the ratio of the thickness h_{S} of the dielectric layer 616 to the combined piezoelectric thickness h_{Piezo}) is identified as “x”, and the ratio for the opposite (or top) coating (e.g., the ratio of the thickness h_{T} of the dielectric layer 612 to the combined piezoelectric thickness h_{Piezo}) is be identified as “y”. Accordingly, the exemplary bulk acoustic resonator achieves the desired coupling coefficient k² of greater than 0.33 when the respective ratios are in the dark region shown in FIG. 7P, which can be defined by the equation:

$${ax}^{2} + bxy + {cy}^{2} + dx + ey - 1 \geq 0 ,$$

where: a=−4.19, b=6.10, c=−3.79, d=−1.87 and e=4.77.

It should also be appreciated that this equation is valid for coating ratios (i.e., top and bottom) between 0 and 1, as defined by the X and Y axes, respectively. In other words, a bulk acoustic resonator that has the defined thickness ratios x and y that satisfy the above-noted equation will advantageously provide a coupling coefficient k² of greater than 0.33 in the A₃ mode having the COP structure in FIG. 6D.

FIG. 8A illustrates a cross-sectional view of an acoustic wave resonator with a complementarily oriented piezoelectric structure according to an exemplary aspect. As shown the acoustic resonator configuration 800A generally corresponds to the XBAR 600A of FIG. 6A, except that dielectric coating layer 614 is not shown. In this example, the piezoelectric layer 610A is considered the COP layer and piezoelectric layer 610B is the standard layer for the acoustic resonator. As further described above, the two piezoelectric layers 610A and 610B are formed of materials (e.g., LN or LT) having different cuts and thus different polarities.

FIGS. 8B and 8C are cross-sectional views of acoustic wave resonators 800B and 800C, respectively, with a complementarily oriented piezoelectric structure according to exemplary aspects in which exemplary Euler angles for each material of each piezoelectric layer 610A and 610B are shown. It is noted that the same components and reference numbers are used as described above with respect to FIG. 6A and the details will not be repeated herein.

According to the exemplary aspect, because of the single-fold rotation about either the X or Y axis, the following 180° rotation along each axis can be provided to achieve opposite polarity (e.g., as shown in FIG. 8A) of the e15 piezoelectric constants. In particular, the following rotation about either the X axis and/or Y axis can be achieved with the following Euler angles according to an exemplary aspect:

$$X - axis rotation : [ λ , μ + 180 , θ ] \\ Y - axis rotation : [ λ , μ + 180 , θ + 180 ]$$

FIGS. 8D to 8G illustrate graphs demonstrating the rotation of 180 degrees to provide for the different Euler angles of the COP structure. Effectively, the rotation provides for the COP structure of two piezoelectric layers (e.g., piezoelectric layers 610A and 610B) such that the first layer (e.g., the COP layer) is formed of a material that comprises first Euler angles and the second layer (e.g., standard layer) is formed of a material that comprises second Euler angles that are rotated by 180° about at least one axis (e.g., the X-axis and/or Y-axis) relative to the material of the first piezoelectric layer.

FIGS. 9A and 9B illustrate charts of piezoelectric stress tensors of an acoustic wave resonator with a complementarily oriented piezoelectric structure according to an exemplary aspect. It should be appreciated that the chart shown in FIG. 9A corresponds to the structure shown in FIG. 8B and corresponding Euler angles. Moreover, the chart shown in FIG. 9B corresponds to the structure shown in FIG. 8C and corresponding Euler angles. As shown in each example chart, the rotating of piezoelectric coefficients that provides for additional Euler angles of [0°,180°,0° ] and [0°,180°,180° ] results in opposite polarity of the e15 piezoelectric tensor that associated for exciting primary A₁ mode. Within the COP layer (e.g., piezoelectric layer 610A of FIGS. 6A-B and 8A-8C), the charge has an opposite polarity from stress field due to the inverse sign of the piezoelectric tensor keeping the charges from cancelling. As a result, a higher coupling k² can be achieved with the COP structure as opposed to only a standard layer as described above with respect to FIG. 2A, for example.

FIG. 10A illustrate a formula for determining coupling according to the COP structure described herein. FIGS. 10B and 10C illustrate charts for the stress profile, uniform E-field throughout the structure and charge profile for a given mode, comparing a standard XBAR structure to an XBAR having a COP structure as described herein. In particular, FIG. 10B illustrates characteristics for a standard acoustic resonator configuration, such as that described above with respect to FIG. 2A. In contrast, FIG. 10C illustrates characteristics for the acoustic resonator 600A having a COP structure as described above with respect to FIG. 6A. As shown, in the A₁ mode, within the COP layer (i.e., piezoelectric layer 610A), the charge has opposite polarity from the stress field. It is also noted that the numerator in the Berlincourt formula of FIG. 10A is the next charge with the piezoelectric layers, and, as such, positive and negative charges lead to a net charge of zero allowing the coupling to vanish for the A₁ mode.

FIGS. 11A-11C illustrate charts for the stress profile, uniform E-field throughout the structure and charge profile for a standard XBAR structure as described herein. In particular, these figures illustrate characteristics for a standard acoustic resonator configuration, such as that described above with respect to FIG. 2A for the A₁ mode (FIG. 11A), S₂ mode (FIG. 11B) and A₃ mode (FIG. 11C).

In contrast, FIGS. 11D-11F illustrate charts for the stress profile, uniform E-field throughout the structure and charge profile for an XBAR structure with a COP structure as described herein. In particular, these figures illustrate characteristics for an acoustic resonator 600A, such as that described above with respect to FIG. 6A for the A₁ mode (FIG. 11D), S₂ mode (FIG. 11E) and A₃ mode (FIG. 11F). In this example, the comparison of the standard structure (i.e., FIGS. 11A-12C) to the COP structure (i.e., FIGS. 11D-12F) is for an uncoated structure (with no dielectric layer) for higher order modes. As shown, for COP structure in FIG. 11D, coupling for S₂ mode becomes large since no cancelation occurs and net charge within piezoelectric layers is large.

On the other hand, FIGS. 12A to 13F compare the structures that includes a dielectric coating layer as described herein. More particularly, FIGS. 12A-13C illustrate charts for the stress profile, uniform E-field throughout the structure and charge profile for a standard XBAR structure as described herein and including a dielectric layer. In particular, these figures illustrate characteristics for a standard acoustic resonator configuration, such as that described above with respect to FIG. 2A for the A₃ mode, in which each structure includes a dielectric layer 212. In these examples, the top coating ratio (h_{T}/h_{Piezo}) is shown to be 0.0 (i.e., FIG. 12A), 0.2 (i.e., FIG. 12B), and 0.5 (i.e., FIG. 12C).

In contrast, FIGS. 12D-12F illustrate charts for the stress profile, uniform E-field throughout the structure and charge profile for an XBAR structure with a COP structure as described herein that also has the top dielectric coating layer. In particular, these figures illustrate characteristics for an acoustic resonator 600A, such as that described above with respect to FIG. 6A for the A₃ mode, in which each structure includes a dielectric layer 612 described above. In these examples, the top coating ratio (h_{T}/h_{Piezo}) is again shown to be 0.0 (i.e., FIG. 12D), 0.2 (i.e., FIG. 12E), and 0.5 (i.e., FIG. 12F). It is again noted that the ratios are approximate ratios that take into account variations in the respective thicknesses that can occur due to manufacturing variances, for example. As shown specifically in FIG. 12F, the charges do not cancel due to the thin dielectric coating layer having a ratio of the thickness of dielectric coating layer to the thickness of the piezoelectric layers to be approximately 0.5, which advantageously results in a large coupling k² for the A₃ mode. In particular, the COP structure of the exemplary aspect with optimal top/bottom coating thickness obtains a much larger normalized coupling k² for the A₃ mode than the 1/9 achieved with A3 mode of a standard XBAR structure as described herein and including a dielectric layer.

In view of the foregoing, a multi-layer complementarily oriented piezoelectric (“COP”) structure with dielectric coating is implemented to achieve high coupling for higher order modes, such as the A₃ mode. In this aspect, the acoustic resonator includes a first piezoelectric layer comprising a material with a first crystallographic orientation; a second piezoelectric layer coupled to the first piezoelectric layer and comprising a material with a second crystallographic orientation, such that a piezoelectric tensor of the second piezoelectric layer is an opposite polarity to a piezoelectric tensor of the fist piezoelectric layer; an interdigital transducer (IDT) including a plurality of interleaved fingers disposed on a surface of the first piezoelectric layer; and a first dielectric coating layer disposed over the IDT and the first piezoelectric layer. The cuts of the piezoelectric layers have a crystallographic orientation with respect to each other such that the corresponding piezoelectric tensor has opposite polarity within the additional one or more COP layers. To further increase coupling k² in higher order modes, such as the A₃ mode, a thickness of the dielectric coating layer can be provided on the acoustic resonator structure.

In general, it is noted that throughout this description, the embodiments and examples shown should be considered as exemplars, rather than limitations on the apparatus and procedures disclosed or claimed. Although many of the examples presented herein involve specific combinations of method acts or system elements, it should be understood that those acts and those elements may be combined in other ways to accomplish the same objectives. With regard to flowcharts, additional and fewer steps may be taken, and the steps as shown may be combined or further refined to achieve the methods described herein. Acts, elements and features discussed only in connection with one embodiment are not intended to be excluded from a similar role in other embodiments.

As used herein, the pair of terms “top” and “bottom” can be interchanged with the pair “front” and “back”. As used herein, “plurality” means two or more. As used herein, a “set” of items may include one or more of such items. As used herein, whether in the written description or the claims, the terms “comprising”, “including”, “carrying”, “having”, “containing”, “involving”, and the like are to be understood to be open-ended, i.e., to mean including but not limited to. Only the transitional phrases “consisting of” and “consisting essentially of”, respectively, are closed or semi-closed transitional phrases with respect to claims. Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements. As used herein, “and/of” means that the listed items are alternatives, but the alternatives also include any combination of the listed items.

What is claimed:

1. An acoustic resonator comprising:
a first piezoelectric layer comprising a material with a first crystallographic orientation;
a second piezoelectric layer attached to the first piezoelectric layer and comprising a material with a second crystallographic orientation, such that a piezoelectric tensor of the second piezoelectric layer is an opposite polarity to a piezoelectric tensor of the first piezoelectric layer;
an interdigital transducer (IDT) including a plurality of interleaved fingers disposed on a surface of the first piezoelectric layer; and
a first dielectric coating layer disposed over the IDT and the first piezoelectric layer, the first dielectric coating layer having a thickness that is less than 0.5 times a combined thickness of the first and second piezoelectric layers.

2. The acoustic resonator according to claim 1, further comprising a second dielectric coating layer disposed over a surface of the second piezoelectric layer that is opposite the first piezoelectric layer.

3. The acoustic resonator according to claim 2, wherein the first and second piezoelectric layers and the IDT are configured such that radio frequency signals applied to the IDT primarily excites a shear acoustic mode in the first and second piezoelectric layers, the shear acoustic mode comprising a bulk shear wave having a propagation direction perpendicular to a direction of a primarily laterally excited electric field generated by the IDT, and the electric field being primarily laterally excited when atomic motion of the bulk shear wave is primarily horizontal in the first and second piezoelectric layers, while the bulk shear wave propagates in a direction primarily perpendicular to the direction of atomic motion.

4. The acoustic resonator according to claim 3, wherein the first and second dielectric coating layers each have a thickness based on a largest net stress of the respective materials of the first and second piezoelectric layers when the primarily shear acoustic mode is excited in the first and second piezoelectric layers.

5. The acoustic resonator according to claim 1, further comprising a substrate that includes a base and an intermediate layer, wherein each of the first and second piezoelectric layers including a portion that is over a cavity that extends at least partially in the intermediate layer of the substrate.

6. The acoustic resonator according to claim 5, wherein the surface of the first piezoelectric layer on which the IDT is disposed faces the cavity.

7. The acoustic resonator according to claim 1, wherein the IDT comprises:
a first busbar and a second busbar that each extend in a first direction from a first end to a second end thereof,
a first plurality of electrode fingers extending from the first busbar in a second direction towards the second busbar, with the second direction intersecting the first direction, and
a second plurality of electrode fingers extending from the second busbar in the second direction towards to the first busbar, such that the first and second plurality of electrode fingers form the plurality of interleaved fingers of the IDT.

8. The acoustic resonator according to claim 1, further comprising a third piezoelectric layer disposed on a surface of the second piezoelectric layer opposite the first piezoelectric layer, the third piezoelectric layer comprising a same material as the first piezoelectric layer having the first crystallographic orientation.

9. The acoustic resonator according to claim 1, wherein the material of first piezoelectric layer comprises first Euler angles and the material of second piezoelectric layer comprises second Euler angles rotated by approximately 180° about at least one axis relative to the first Euler angles.

10. The acoustic resonator according to claim 1, wherein the acoustic resonator is configured to operate in a third order antisymmetric (A3) mode and the first dielectric coating layer has a thickness configured to increase a coupling coefficient of the acoustic resonator in the A3 mode.

11. An acoustic resonator configured for operating in at least one of a third order antisymmetric (A3) mode and fourth order symmetric (S4) mode, the acoustic resonator comprising:
a first piezoelectric layer comprising a material with a first crystallographic orientation;
a second piezoelectric layer coupled to the first piezoelectric layer and comprising a material with a second crystallographic orientation, such that a piezoelectric tensor of the second piezoelectric layer is an opposite polarity to a piezoelectric tensor of the first piezoelectric layer;
an interdigital transducer (IDT) including a plurality of interleaved fingers disposed on a surface of the first piezoelectric layer; and
a first dielectric coating layer disposed over the IDT and the first piezoelectric layer.

12. The acoustic resonator according to claim 11, wherein the first dielectric coating layer has a thickness that is less than 0.5 times a combined thickness of the first and second piezoelectric layers.

13. The acoustic resonator according to claim 11, wherein the first dielectric coating layer has a thickness that is between 0.15 and 1.0 times a combined thickness of the first and second piezoelectric layers and the acoustic resonator is configured to operate in the third order antisymmetric (A3) mode.

14. The acoustic resonator according to claim 13, further comprising:
a second dielectric coating layer disposed over a surface of the second piezoelectric layer that is opposite the first piezoelectric layer, the second dielectric layer have a thickness y,
wherein 0≤y≤−0.35x²+1.23x−0.18,
wherein x is a ratio of the thickness of the first dielectric coating layer to the combined thickness of the first and second piezoelectric layers, and
wherein y is a ratio of a thickness of the second dielectric coating layer to the combined thickness of the first and second piezoelectric layers.

15. The acoustic resonator according to claim 11, further comprising:
a second dielectric coating layer disposed over a surface of the second piezoelectric layer that is opposite the first piezoelectric layer, the second dielectric layer have a thickness that is between 0.15 and 1.0 times a combined thickness of the first and second piezoelectric dielectric layers,
wherein 0≤x≤−0.35y²+1.23y−0.18,
wherein x is a ratio of a thickness of the first dielectric coating layer to the combined thickness of the first and second piezoelectric layers, and
wherein y is a ratio of the thickness of the second dielectric coating layer to the combined thickness of the first and second piezoelectric layers.

16. The acoustic resonator according to claim 15, wherein the first and second piezoelectric layers and the IDT are configured such that radio frequency signals applied to the IDT excites a primary shear acoustic mode in the first and second piezoelectric layers, the shear acoustic mode comprising a bulk shear wave having a propagation direction perpendicular to a direction of a primarily laterally excited electric field generated by the IDT, and the electric field being primarily laterally excited when atomic motion of the bulk shear wave is primarily horizontal in the first and second piezoelectric layers, while the bulk shear wave propagates in a direction primarily perpendicular to the direction of atomic motion.

17. The acoustic resonator according to claim 16, wherein the first and second dielectric coating layers each have a thickness based on a largest net stress of the respective materials of the first and second piezoelectric layers when the primary shear acoustic mode is excited in the first and second piezoelectric layers.

18. The acoustic resonator according to claim 11, further comprising a third piezoelectric layer disposed on a surface of the second piezoelectric layer opposite the first piezoelectric layer, the third piezoelectric layer comprising a same material as the first piezoelectric layer having the first crystallographic orientation.

19. The acoustic resonator according to claim 11, wherein the material of first piezoelectric layer comprises first Euler angles and the material of second piezoelectric layer comprises second Euler angles rotated by approximately 180° about at least one axis relative to the first Euler angle.

20. A radio frequency module, comprising:
a filter device having a plurality of acoustic resonators configured to operate in at least one of a third order antisymmetric (A3) mode and fourth order symmetric (S4) mode; and
a radio frequency circuit coupled to the filter device, the filter device and the radio frequency circuit being enclosed within a common package,
wherein at least one of the plurality of acoustic resonators includes:
a first piezoelectric layer comprising a material with a first crystallographic orientation;
a second piezoelectric layer coupled to the first piezoelectric layer and comprising a material with a second crystallographic orientation, such that a piezoelectric tensor of the second piezoelectric layer is an opposite polarity to a piezoelectric tensor of the first piezoelectric layer;
an interdigital transducer (IDT) including a plurality of interleaved fingers disposed on a surface of the first piezoelectric layer;
a first dielectric coating layer disposed over the IDT and the first piezoelectric layer; and
a second dielectric coating layer disposed over a surface of the second piezoelectric layer that is opposite the first piezoelectric layer,
wherein one of the first and second dielectric layers has a thickness that is between 0.15 and 1.0 times a combined thickness of the first and second piezoelectric layers, and
wherein another of the first and second dielectric layers has thickness, such that 0≤y≤−0.35x²+1.23x−0.18,
wherein x is a ratio of the thickness of the first dielectric coating layer to the combined thickness of the first and second piezoelectric layers, and
wherein y is a ratio of a thickness of the second dielectric coating layer to the combined thickness of the first and second piezoelectric layers.
